(19) United States
(12) Patent Application Publication
(10) Pub. No.: US 2024/0313718 A1
(43) Pub. Date: Sep. 19, 2024

(54) POWER AMPLIFIER CIRCUIT, POWER AMPLIFIER APPARATUS, AND IMPEDANCE MATCHING DEVICE

(71) Applicant: Murata Manufacturing Co., Ltd., Kyoto (JP)

(72) Inventors: Yuri HONDA, Kyoto (JP); Takayuki KAWANO, Kyoto (JP); Fumitoshi DERIHA, Kyoto (JP)

(21) Appl. No.: 18/669,827

(22) Filed: May 21, 2024

Related U.S. Application Data
(63) Continuation of application No. PCT/JP2022/045023, filed on Dec. 7, 2022.

(30) Foreign Application Priority Data
Dec. 7, 2021 (JP) 2021-198551

(51) Int. Cl. H03F 3/24; H03F 1/56; H03F 3/45

(52) U.S. Cl. CPC H03F 3/245; H03F 1/565; H03F 3/45076; H03F 2200/09; H03F 2200/451

(57) ABSTRACT

A power amplifier circuit includes a first amplifier that amplifies a first signal that is one of balanced signals and outputs a first amplified signal from a first output terminal, a second amplifier that amplifies a second signal that is another of the balanced signals and outputs a second amplified signal from a second output terminal, a balun that generates a third signal from the first amplified signal and the second amplified signal, and a matching circuit that is provided between the first amplifier and the second amplifier, and the balun.

### CROSS REFERENCE TO RELATED APPLICATION

This is a continuation of International Application No. PCT/JP2022/045023 filed on Dec. 7, 2022 which claims priority from Japanese Patent Application No. 2021-198551 filed on Dec. 7, 2021. The contents of these applications are incorporated herein by reference in their entireties.

### BACKGROUND OF THE DISCLOSURE

### Field of the Disclosure

The present disclosure relates to a power amplifier circuit, a power amplifier apparatus, and an impedance matching device.

### Description of the Related Art

There is a third harmonic-wave control circuit that optimizes the impedance of the fundamental wave and the third harmonic wave (see Patent Document 1, for example).

Patent Document 1: Japanese Unexamined Patent Application Publication No. 2001-257546

### BRIEF SUMMARY OF THE DISCLOSURE

However, in the third harmonic-wave control circuit described in Patent Document 1, it is difficult to optimize the impedance of the second harmonic wave.

The present disclosure has been made in view of the above circumstances, and a possible benefit of the present disclosure is to provide a power amplifier circuit, a power amplifier apparatus, and an impedance matching device capable of controlling impedance of a second harmonic wave and improving linearity.

According to an aspect of the present disclosure, a power amplifier circuit includes a first amplifier that amplifies a first signal that is one of balanced signals and outputs a first amplified signal from a first output terminal, a second amplifier that amplifies a second signal that is another of the balanced signals and outputs a second amplified signal from a second output terminal, a balun that generates a third signal from the first amplified signal and the second amplified signal, and a matching circuit that is provided between the first amplifier and the second amplifier, and the balun. The matching circuit includes a first capacitor having a first end connected to the first output terminal and a second end, a second capacitor having a first end connected to the second output terminal and a second end connected to the second end of the first capacitor, and a wiring having a first end connected to the second end of the first capacitor and a second end connected to a ground.

According to another aspect of the present disclosure, an impedance matching device includes a first conductive portion that has a first end portion electrically connected to a reference electrode to which a reference potential is supplied, and a second end portion, and extends in a first direction, and a second conductive portion that has a third end portion and a fourth end portion and extends in a second direction intersecting with the first direction. The second conductive portion includes a first connection portion that is electrically connected to a first output terminal of a first amplifier that is one in a differential pair, through a first capacitor, a second connection portion that is electrically connected to a second output terminal of a second amplifier that is another in the differential pair, through a second capacitor, and a third connection portion that is electrically connected to the second end portion of the first conductive portion.

According to the present disclosure, it is possible to provide a power amplifier circuit, a power amplifier apparatus, and an impedance matching device capable of controlling the impedance of a second harmonic wave and improving linearity.

### BRIEF DESCRIPTION OF THE SEVERAL VIEWS OF THE DRAWINGS

FIG. 1 is a circuit diagram of a power amplifier circuit 101.

FIG. 2 is a diagram for describing how a circuit appears in an even-order harmonic wave.

FIG. 3 is a diagram for describing how a circuit appears in a fundamental wave and an odd-order harmonic wave.

FIG. 4 is a Smith chart illustrating a simulation result of reflection coefficients Γ2 and Γ3 based on impedance ZLp in the power amplifier circuit 101.

FIG. 5 is a diagram illustrating an example of a simulation result of a relationship between a phase angle φ of the reflection coefficient Γ2 and PAE in the power amplifier circuit 101.

FIG. 6 is a diagram illustrating an example of a simulation result of a relationship between a phase angle φ of the reflection coefficient Γ3 and the PAE in the power amplifier circuit 101.

FIG. 7 is a diagram illustrating an example of a simulation result of AM-AM characteristics in the power amplifier circuit 101.

FIG. 8 is a diagram illustrating an example of a simulation result of AM-PM characteristics in the power amplifier circuit 101.

FIG. 9 is a diagram illustrating an example of an output power change of an input-output phase difference in the power amplifier circuit 101.

FIG. 10 is a circuit diagram of a power amplifier circuit 102.

FIG. 11 is a circuit diagram of a power amplifier circuit 103.

FIG. 12 is a diagram illustrating a semiconductor device 1.

FIG. 13 is a diagram schematically illustrating a layout of a semiconductor chip 11.

FIG. 14 is a diagram illustrating a semiconductor device 2.

FIG. 15 is a diagram illustrating a semiconductor device 3.

FIG. 16 is a diagram illustrating a semiconductor device 4.

FIG. 17 is a diagram schematically illustrating cross sections of the semiconductor chip 11 in which a matching circuit 61 is formed, and a printed board 12, the cross sections being parallel to an xz plane.

FIG. 18 is a diagram illustrating a semiconductor device 5.

FIG. 19 is a diagram schematically illustrating cross sections of a semiconductor chip 11 in which a matching circuit 61 is formed, and a printed board 12, the cross sections being parallel to the xz plane.

FIG. 20 is a plan view of a dielectric layer 224 and a wiring layer 234 when viewed from an upper side.

FIG. 21 is a diagram illustrating a semiconductor device 6.

FIG. 22 is a diagram schematically illustrating cross sections of a semiconductor chip 11 in which a matching circuit 61 is formed, and a printed board 12, the cross sections being parallel to the xz plane.

FIG. 23 is a diagram schematically illustrating each cross section of the printed board 12 in which a balun 42 is formed, the cross section being parallel to an xy plane.

FIG. 24 is a diagram schematically illustrating each cross section of a printed board 12 in which a balun 42 is formed, the cross section being parallel to the xy plane.

FIG. 25 is a diagram illustrating a semiconductor device 7.

FIG. 26 is a diagram illustrating a semiconductor device 8.

FIG. 27 is a diagram schematically illustrating cross sections of a semiconductor chip 11 in which a matching circuit 61 is formed, and a printed board 12, the cross sections being parallel to the xz plane.

FIG. 28 is a diagram schematically illustrating each cross section of a semiconductor chip 11 and a printed board 12, which is parallel to the xy plane.

FIG. 29 is a diagram schematically illustrating each cross section of a printed board 12, which is parallel to the xy plane.

### DETAILED DESCRIPTION OF THE DISCLOSURE

Hereinafter, embodiments of the present disclosure will be described in detail with reference to the accompanying drawings.

The same elements are denoted by the same reference signs, and the repetitive descriptions are omitted as much as possible.

### First Embodiment

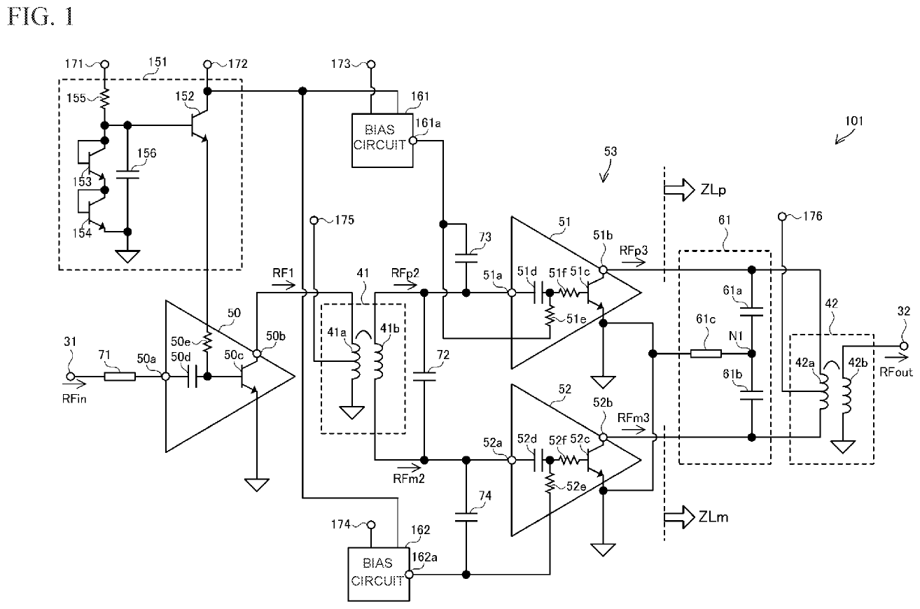

A power amplifier circuit 101 according to a first embodiment will be described. FIG. 1 is a circuit diagram of the power amplifier circuit 101. As illustrated in FIG. 1, the power amplifier circuit 101 is a two-stage amplifier circuit that amplifies an input signal RFin and outputs an output signal RFout (third signal).

The power amplifier circuit 101 includes baluns 41 and 42, a driver-stage amplifier 50, a differential pair 53, a matching circuit 61, a microstrip line 71, capacitors 72, 73, and 74, a driver-stage bias supply circuit 151, and power-stage bias supply circuits 161 and 162. The differential pair 53 includes power-stage amplifiers 51 (first amplifier) and 52 (second amplifier).

In the present embodiment, the amplifiers such as the driver-stage amplifier 50 and the power-stage amplifiers 51 and 52 are configured by, for example, bipolar transistors such as heterojunction bipolar transistors (HBT). The amplifier may be configured by another transistor such as a field-effect transistor (MOSFET: metal-oxide-semiconductor field-effect transistor). In this case, a base, a collector, and an emitter may be read as a gate, a drain, and a source, respectively.

The driver-stage amplifier 50 amplifies the input signal RFin supplied from an input terminal 31 to an input terminal 50a through the microstrip line 71, and outputs an amplified signal RF1 from an output terminal 50b.

In detail, the driver-stage amplifier 50 includes an amplification transistor 50c, a capacitor 50d, and a resistor element 50e. The amplification transistor 50c has a collector connected to the output terminal 50b, a base connected to the input terminal 50a through the capacitor 50d, and an emitter connected to the ground.

The driver-stage bias supply circuit 151 supplies a bias to the base of the amplification transistor 50c through the resistor element 50e. In detail, the driver-stage bias supply circuit 151 includes a bias transistor 152, transistors 153 and 154, a resistor element 155, and a capacitor 156.

The resistor element 155 has a first end, to which a current is supplied from a current supply terminal 171, and a second end. The transistor 153 is diode-connected, and has a collector and a base that are connected to the second end of the resistor element 155, and an emitter. The transistor 154 is diode-connected, and has a collector and a base that are connected to the emitter of the transistor 153, and an emitter connected to the ground. The capacitor 156 has a first end connected to the second end of the resistor element 155 and a second end connected to the ground.

The bias transistor 152 has a collector connected to a battery voltage supply terminal 172, a base connected to the second end of the resistor element 155, and an emitter connected to the base of the amplification transistor 50c through the resistor element 50e.

The balun 41 generates an amplified signal RFp2 (first signal) and an RFm2 (second signal) which are balanced signals, from the amplified signal RF1 which is an unbalanced signal.

In detail, the balun 41 includes inductors 41a and 41b. The inductor 41a has a first end connected to the output terminal 50b of the driver-stage amplifier 50, an intermediate tap connected to the power supply voltage supply terminal 175, and a second end connected to the ground.

The inductor 41b is electromagnetically coupled to the inductor 41a, and has a first end that outputs the amplified signal RFp2 that is one of the balanced signals and a second end that outputs the amplified signal RFm2 that is the other of the balanced signals. The phase of the amplified signal RFp2 differs from the phase of the amplified signal RFm2 by approximately 180°. The difference between the phase of the amplified signal RFp2 and the phase of the amplified signal RFm2 may largely differ from 180° due to the imbalance in a wiring length of the circuit or the like.

The capacitor 72 has a first end connected to a first end of the inductor 41b, and a second end connected to a second end of the inductor 41b.

The power-stage bias supply circuit 161 operates by a voltage supplied from the battery voltage supply terminal 172. The power-stage bias supply circuit 161 generates a bias voltage to be supplied to the power-stage amplifier 51 and outputs the generated bias voltage from the output terminal 161a, in accordance with a control signal inputted from a control signal supply terminal 173.

The power-stage amplifier 51 amplifies the amplified signal RFp2 supplied from the first end of the inductor 41b to the input terminal 51a, and outputs an amplified signal RFp3 (first amplified signal) from the output terminal 51b (first output terminal).

In detail, the power-stage amplifier 51 includes an amplification transistor 51c, a capacitor 51d, and resistor elements 51e and 51f. The capacitor 51d has a first end that is connected to the first end of the inductor 41b through the input terminal 51a, and a second end. The power-stage amplifier 51 operates, for example, as an inverse class-F amplifier.

The amplification transistor 51c has a collector connected to the output terminal 51b, a base connected to the second end of the capacitor 51d through the resistor element 51f, and an emitter connected to the ground.

The resistor element 51e has a first end that is connected to the output terminal 161a of the power-stage bias supply circuit 161 and a second end that is connected to the second end of the capacitor 51d. The capacitor 73 has a first end that is connected to the output terminal 161a of the power-stage bias supply circuit 161 and a second end that is connected to the input terminal 51a of the power-stage amplifier 51.

The power-stage bias supply circuit 162 operates by the voltage supplied from the battery voltage supply terminal 172. The power-stage bias supply circuit 162 generates a bias voltage to be supplied to the power-stage amplifier 52 and outputs the generated bias voltage from the output terminal 162a, in accordance with a control signal inputted from a control signal supply terminal 174.

The power-stage amplifier 52 amplifies the amplified signal RFm2 supplied from the second end of the inductor 41b to the input terminal 52a, and outputs an amplified signal RFm3 (second amplified signal) from the output terminal 52b (second output terminal). The power-stage amplifier 52 operates, for example, as an inverse class-F amplifier.

In detail, the power-stage amplifier 52 includes an amplification transistor 52c, a capacitor 52d, and resistor elements 52e and 52f. The capacitor 52d has a first end that is connected to the second end of the inductor 41b through the input terminal 52a, and a second end.

The amplification transistor 52c has a collector connected to the output terminal 52b, a base connected to the second end of the capacitor 52d through the resistor element 52f, and an emitter connected to the ground.

The resistor element 52e has a first end that is connected to the output terminal 162a of the power-stage bias supply circuit 162 and a second end that is connected to the second end of the capacitor 52d. The capacitor 74 has a first end that is connected to the output terminal 162a of the power-stage bias supply circuit 162 and a second end that is connected to the input terminal 52a of the power-stage amplifier 52.

The balun 42 generates an output signal RFout from the amplified signals RFp3 and RFm3. In detail, the balun 42 includes inductors 42a and 42b.

The inductor 42a has a first end that is connected to the output terminal 51b of the power-stage amplifier 51, an intermediate tap that is connected to the power supply voltage supply terminal 176, and a second end that is connected to the output terminal 52b of the power-stage amplifier 52.

The inductor 42b has a first end connected to an output terminal 32 and a second end connected to the ground. The inductor 42b is electromagnetically coupled to the inductor 42a, and outputs the output signal RFout which is an unbalanced signal from the first end to the output terminal 32.

The matching circuit 61 is provided between the differential pair 53 and the balun 42, and performs the impedance matching between the differential pair 53 and the balun 42. In the present embodiment, the matching circuit 61 includes capacitors 61a (first capacitor) and 61b (second capacitor), and a microstrip line 61c (wiring).

The capacitor 61a has a first end that is connected to the output terminal 51b of the power-stage amplifier 51 and a second end that is connected to a node N1. The capacitor 61b has a first end that is connected to the output terminal 52b of the power-stage amplifier 52 and a second end that is connected to the node N1. The microstrip line 61c has a first end connected to the node N1 and a second end connected to the ground. The microstrip line 61c is formed, for example, in a straight line shape.

### Actions and Effects

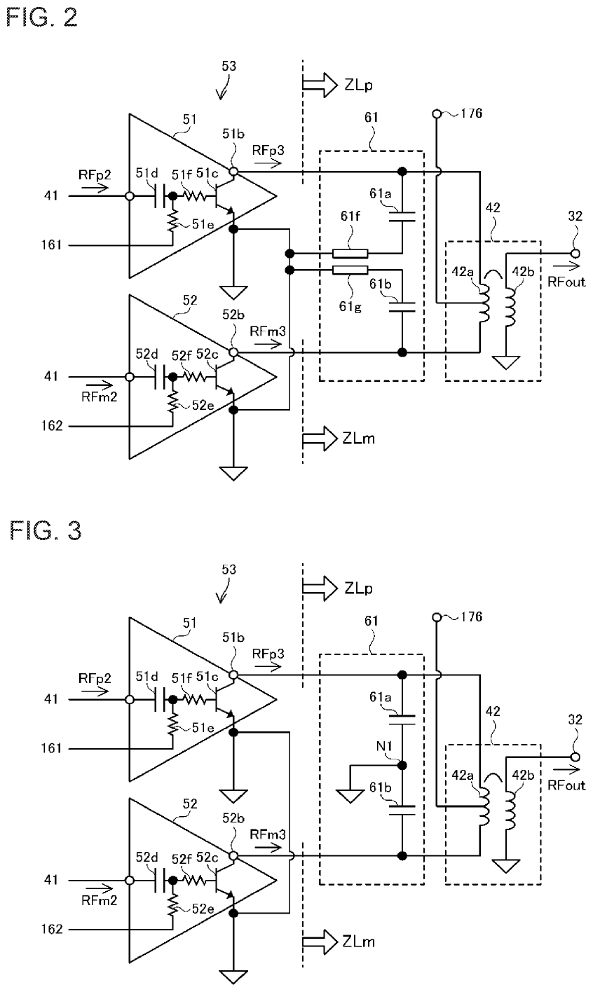

FIG. 2 is a diagram for describing how the circuit appears in an even-order harmonic wave. As illustrated in FIG. 2, in the case of even-order harmonic waves, the phase of the amplified signal RFp3 is substantially the same as the phase of the amplified signal RFm3, and thus, the potential of the output terminal 51b of the power-stage amplifier 51 is substantially the same as the potential of the output terminal 52b of the power-stage amplifier 52.

Therefore, no current flows from the output terminal 51b to the output terminal 52b through the capacitors 61a and 61b (see FIG. 1). Thus, from the output terminal 51b, it seems that the output terminal 51b is not connected to the output terminal 52b through the capacitors 61a and 61b (see FIG. 2).

On the other hand, since the potential of the output terminal 51b is different from the potential of the ground, a current flows from the output terminal 51b to the ground through the capacitor 61a and the microstrip line 61c (see FIG. 1). Thus, from the output terminal 51b, it seems that the output terminal 51b is connected to the ground through the capacitor 61a and the microstrip line 61f (see FIG. 2).

The impedance ZLp for an even-order harmonic wave when the matching circuit 61 is viewed from the output terminal 51b can be adjusted by the capacitance of the capacitor 61a and the inductance of the microstrip line 61f. Similarly, the impedance ZLm for an odd-order harmonic wave when the matching circuit 61 is viewed from the output terminal 52b can be adjusted by the capacitance of the capacitor 61b and the inductance of a microstrip line 61g.

FIG. 3 is a diagram for describing how the circuit appears in a fundamental wave and an odd-order harmonic wave. As illustrated in FIG. 3, in the case of the fundamental wave and the odd-order harmonic wave, the phase of the amplified signal RFp3 is different from the phase of the amplified signal RFm3 by approximately 180°. Thus, imaginary short occurs at the node N1. Thus, from the output terminal 51b, it seems that the output terminal 51b is connected to the ground through the capacitor 61a. Similarly, from the output terminal 52b, it seems that the output terminal 52b is connected to the ground through the capacitor 61b.

The impedance ZLp for the fundamental wave and the odd-order harmonic wave when the matching circuit 61 is viewed from the output terminal 51b can be adjusted by the capacitance of the capacitor 61a. Similarly, the impedance ZLm for the fundamental wave and the odd-order harmonic wave when the matching circuit 61 is viewed from the output terminal 52b can be adjusted by the capacitance of the capacitor 61b.

The inventor simulated a reflection coefficient Γ based on the impedance ZLp when the matching circuit 61 is viewed from the output terminal 51b, by using a circuit constant of each circuit element in the power amplifier circuit 101 as a parameter. The “reflection coefficient Γ” referred to here is a reflection coefficient when the impedance at the frequency of the fundamental wave is defined as a normalized impedance (Z0). Specifically, the reflection coefficient Γ is a reflection coefficient (may be referred to as a reflection coefficient Γ2 below) for the second harmonic wave and a reflection coefficient (may be referred to as a reflection coefficient Γ3 below) for the third harmonic wave.

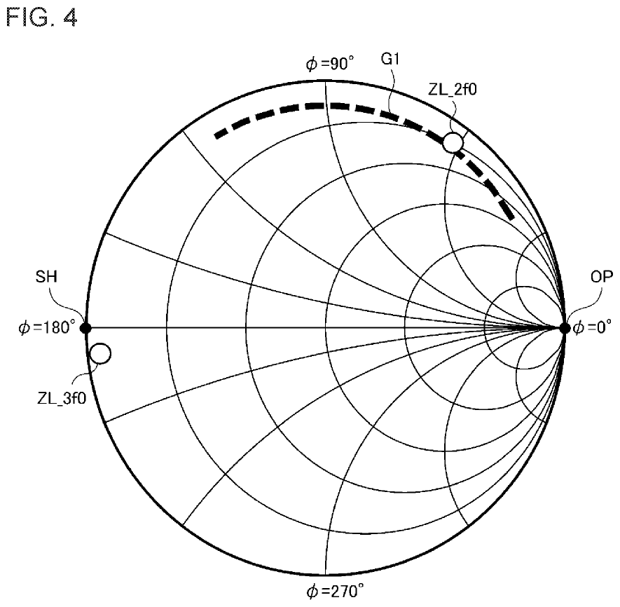

FIG. 4 is a Smith chart illustrating a simulation result of the reflection coefficients Γ2 and Γ3 based on the impedance ZLp in the power amplifier circuit 101. As illustrated in FIG. 4, the reflection coefficient Γ3 for the third harmonic wave is represented by a point ZL_3f0 located near a point SH having a magnitude ρ of 1 and a phase angle φ of 180°. That is, the impedance ZLp for the third harmonic wave becomes substantially short.

Meanwhile, in a configuration in which the matching circuit 61 is removed from the power amplifier circuit 101, the output terminal 51b of the power-stage amplifier 51 and the output terminal 52b of the power-stage amplifier 52 is disconnected. Thus, the reflection coefficient Γ2 is represented by a point (not illustrated) located near a point OP having a magnitude ρ of 1 and a phase angle φ of 0°.

On the other hand, in the power amplifier circuit 101, the phase angle Φ of the reflection coefficient Γ2 can be set to 30° to 120° by adjusting the capacitance of the capacitor 61a and the inductance of the microstrip line 61c. As a result, for each of the power-stage amplifiers 51 and 52, the input-output phase difference of a signal voltage with respect to a power change of the output signal RFout can be brought close to being flat. Here, the input-output phase difference of the signal voltage is a change in the phase of the signal voltage when the output terminal 51b or 52b is viewed from the input terminal 51a or 52a, respectively. By bringing the input-output phase difference of the signal voltage close to being flat, it is possible to improve the linearity of a relationship between the input and the output of each of the power-stage amplifiers 51 and 52. Detailed description will be made below.

### (Phase Angle Change of Power-Added Efficiency (PAE))

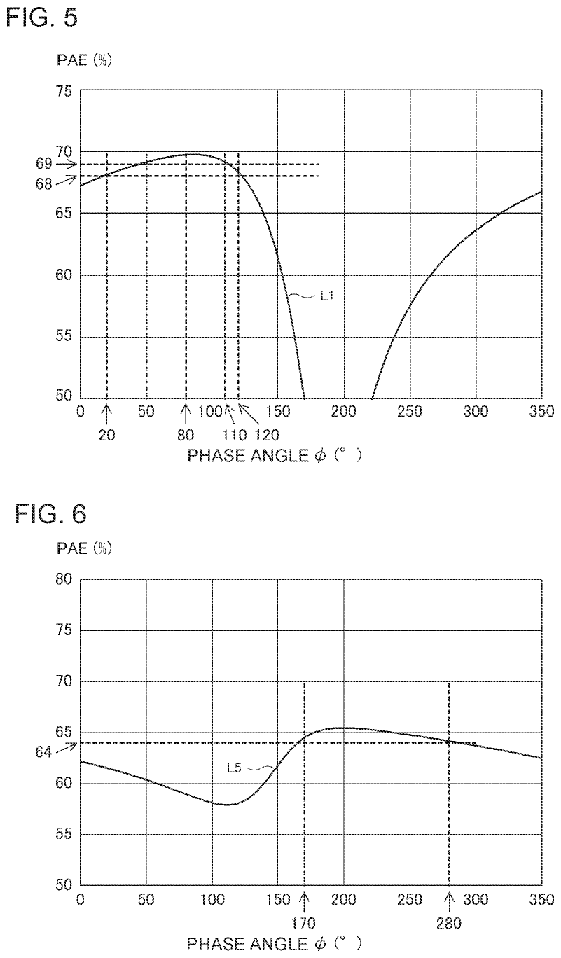

FIG. 5 is a diagram illustrating an example of a simulation result of a relationship between the phase angle φ of the reflection coefficient Γ2 and PAE in the power amplifier circuit 101. In FIG. 5, the horizontal axis indicates the phase angle φ of the reflection coefficient Γ2 in a unit of “°”, and the vertical axis indicates the PAE in a unit of “%”.

As illustrated in FIG. 5, a curve L1 indicates a change in PAE with respect to the phase angle change in a case where the output power of the power-stage amplifier 51 is 33.5 dBm and the magnitude ρ of the reflection coefficient Γ2 is 0.9.

When the phase angle φ is 20° or more and 120° or less, it is possible to realize PAE of 68% or higher, at which favorable characteristics can be generally obtained. Specifically, when the phase angle φ is 20° or more and 120° or less, it is possible to realize PAE of 68% or more, which is higher than 67%, at which the phase angle of 0° in the configuration in which the matching circuit 61 is removed from the above-described power amplifier circuit 101. Preferably, when the phase angle φ is 50° or more and 110° or less, it is possible to realize more favorable PAE of 69%.

When the phase angle φ is measured, for example, a method of combining a measurement result of the circuit constant of each circuit element constituting the matching circuit and a measurement result of the impedance of a pattern connected to the matching circuit, on a printed board (for example, impedance evaluation result using a probe), and the like can be used.

FIG. 6 is a diagram illustrating an example of a simulation result of a relationship between the phase angle φ of the reflection coefficient Γ3 and the PAE in the power amplifier circuit 101. In FIG. 6, the horizontal axis indicates the phase angle φ of the reflection coefficient Γ3 in a unit of “°”, and the vertical axis indicates the PAE in a unit of “%”.

As illustrated in FIG. 6, a curve L5 indicates a change in PAE with respect to the phase angle change in a case where the output power of the power-stage amplifier 51 is 35.5 dBm and the magnitude ρ of the reflection coefficient Γ3 is 0.9.

Although the peak value of the PAE decreases to 66% because simulation conditions are different from the case illustrated in FIG. 5, it is possible to realize favorable PAE of 64% or more, which is reduced by 2 points from the peak value of the PAE, that is, 66%, when the phase angle φ is 170° or more and 280° or less.

### (Phase Angle Change of AM-AM Characteristics)

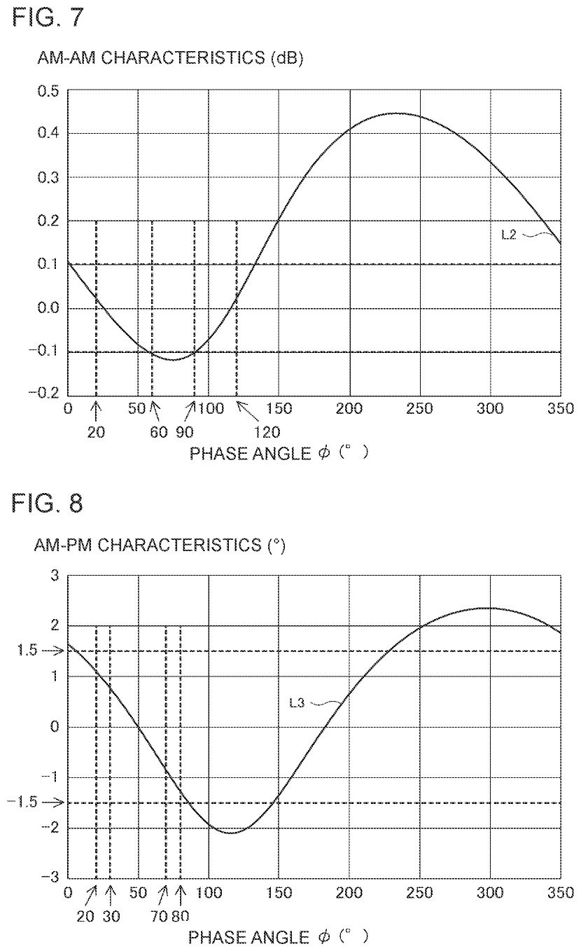

FIG. 7 is a diagram illustrating an example of a simulation result of AM-AM characteristics in the power amplifier circuit 101. In FIG. 7, the horizontal axis indicates the phase angle φ of the reflection coefficient Γ2 in a unit of “°”, and the vertical axis indicates the AM-AM characteristics in a unit of “dB”.

As illustrated in FIG. 7, a curve L2 indicates a change in AM-AM characteristics with respect to the phase angle change in a case where the output power of the power-stage amplifier 51 is 29 dBm and the magnitude ρ of the reflection coefficient Γ2 is 0.9. Here, the AM-AM characteristics means a ratio between the amplitude of the amplified signal RFp2 inputted to the power-stage amplifier 51 and the amplitude of the amplified signal RFp3 outputted from the power-stage amplifier 51, and is obtained by subtracting the ratio when the output power is 29 dBm from the ratio when the output power is sufficiently low (5 dBm in FIG. 7).

When the phase angle φ is 20° or more and 60° or less and when the phase angle φ is 90° or more and 120° or less, it is possible to realize favorable PAE (see FIG. 5) of 68% or more and the AM-AM characteristics of −0.1 or more and 0.1 or less, at which the favorable characteristics can be obtained.

### (Phase Angle Change of AM-PM Characteristics)

FIG. 8 is a diagram illustrating an example of a simulation result of AM-PM characteristics in the power amplifier circuit 101. In FIG. 8, the horizontal axis indicates the phase angle φ of the reflection coefficient Γ2 in a unit of “°”, and the vertical axis indicates the AM-PM characteristics in a unit of “°”.

As illustrated in FIG. 8, a curve L3 indicates a change in AM-PM characteristics with respect to the phase angle change in a case where the output power of the power-stage amplifier 51 is 29 dBm and the magnitude ρ of the reflection coefficient Γ2 is 0.9. Here, the AM-PM characteristics means a phase angle when a complex voltage of the amplified signal RFp3 outputted from the power-stage amplifier 51 is divided by a complex voltage of the amplified signal RFp2 inputted to the power-stage amplifier 51, and is obtained by subtracting the phase angle when the output power is 29 dBm from the phase angle when the output power is sufficiently low (5 dBm in FIG. 8).

When the phase angle φ is 20° or more and 80° or less, it is possible to realize favorable PAE (see FIG. 5) of 68% or more and the AM-PM characteristics of −1.5 or more and 1.5 or less, at which the favorable characteristics can be obtained. Further, when the phase angle φ is 30° or more and 70° or less, it is possible to realize favorable PAE (see FIG. 5) of 68% or more and the AM-PM characteristics of −1.0 or more and 1.0 or less, at which the further favorable characteristics can be obtained.

### (Output Power Change of Input-Output Phase Difference)

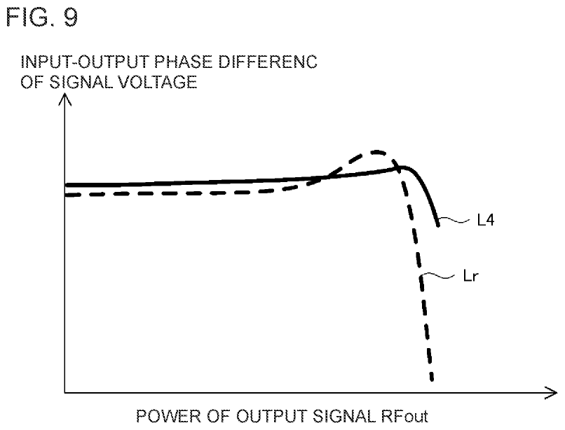

FIG. 9 is a diagram illustrating an example of the input-output phase difference of the signal voltage with respect to the power change of the output signal. In FIG. 9, the horizontal axis indicates the power of the output signal RFout, and the vertical axis indicates the input-output phase difference of the signal voltage.

As illustrated in FIG. 9, a curve L4 indicates the input-output phase difference of the signal voltage with respect to the power change of the output signal RFout in the power amplifier circuit 101. A curve Lr indicates the input-output phase difference of the signal voltage with respect to the power change of the output signal in the configuration in which the matching circuit 61 is removed from the power amplifier circuit 101. As indicated by the curves L4 and Lr, in the power amplifier circuit 101, the input-output phase difference of the signal voltage can be brought close to being flat than the above configuration. That is, it is possible to improve the linearity of the input-output phase difference with respect to the output power. As a result, it is possible to improve the linearity of the relationship between the input and the output of each of the power-stage amplifiers 51 and 52.

### Second Embodiment

A power amplifier circuit 102 according to a second embodiment will be described. In the second and subsequent embodiments, descriptions of matters common to the first embodiment will be omitted, and only differences will be described. In particular, similar actions and effects achieved by the similar configuration will not be repeated in each embodiment.

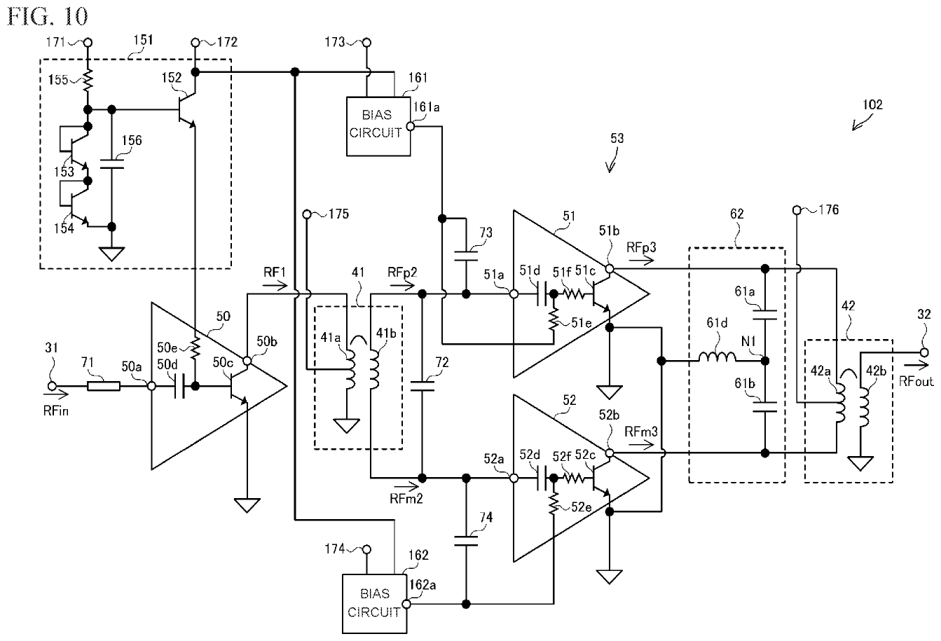

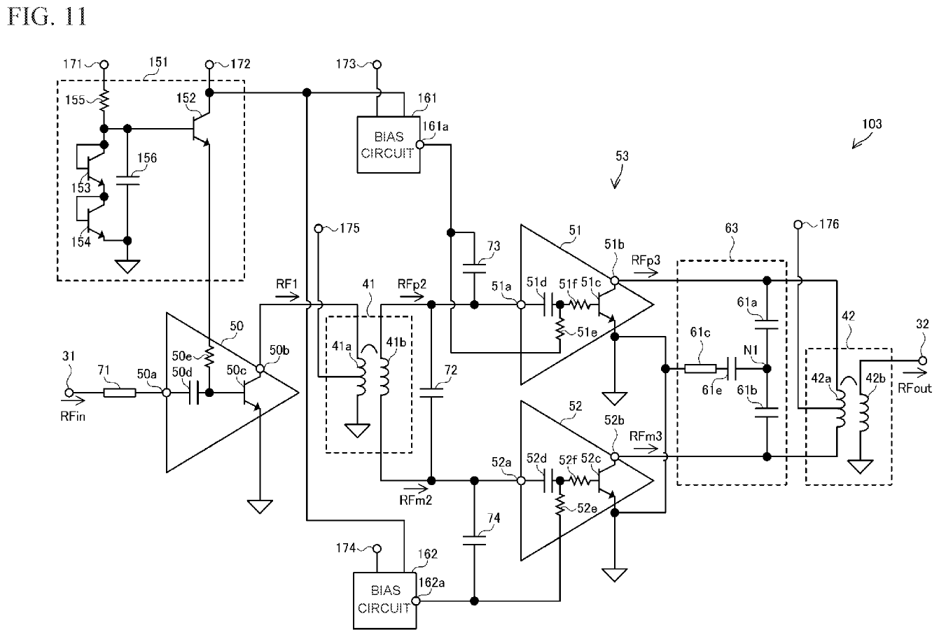

FIG. 10 is a circuit diagram of the power amplifier circuit 102. As illustrated in FIG. 10, the power amplifier circuit 102 according to the second embodiment is different from the power amplifier circuit 101 according to the first embodiment in that an inductor is provided between the node N1 and the ground.

The power amplifier circuit 102 includes a matching circuit 62 instead of the matching circuit 61, as compared with the power amplifier circuit 101 illustrated in FIG. 1. The matching circuit 62 includes an inductor 61d (wiring) instead of the microstrip line 61c, as compared with the matching circuit 61 illustrated in FIG. 1.

The inductor 61d has a first end connected to the node N1 and a second end connected to the ground. The inductor 61d is formed, for example, in a spiral shape. The inductor 61d may be formed in such a manner that the entire inductor 61d is formed in a spiral shape, or a portion of the inductor 61d is formed in a spiral shape and another portion of the inductor 61d is formed in a straight line shape. In addition, the “spiral shape” is not limited to a shape in which a wiring is wound over a plurality of turns. It is assumed that the spiral shape also includes, for example, a shape in which the wiring is wound by one or more turns and less than two turns or a shape in which an extending direction of the wiring changes at one or more places (specifically, a shape in which the extending direction of the wiring changes at one or a plurality of places, and the wiring is wound by ⅓ turn or ½ turn as a whole).

### Third Embodiment

A power amplifier circuit 103 according to a third embodiment will be described. FIG. 11 is a circuit diagram of the power amplifier circuit 103. As illustrated in FIG. 11, the power amplifier circuit 103 according to the third embodiment is different from the power amplifier circuit 101 according to the first embodiment in that a capacitor connected in series to the microstrip line 61c is further provided between the node N1 and the ground.

The power amplifier circuit 103 includes a matching circuit 63 instead of the matching circuit 61, as compared with the power amplifier circuit 101 illustrated in FIG. 1. The matching circuit 63 further includes a capacitor 61e (third capacitor), as compared with the matching circuit 61 illustrated in FIG. 1.

The capacitor 61e has a first end connected to the node N1, and a second end. The microstrip line 61c has a first end connected to a second end of the capacitor 61e and a second end connected to the ground.

A configuration in which the first end of the capacitor 61e is connected to the ground and the second end of the microstrip line 61c is connected to the node N1 may be adopted. Further, a configuration in which an inductor 61d (see FIG. 10) is connected instead of the microstrip line 61c may be adopted.

### Fourth Embodiment

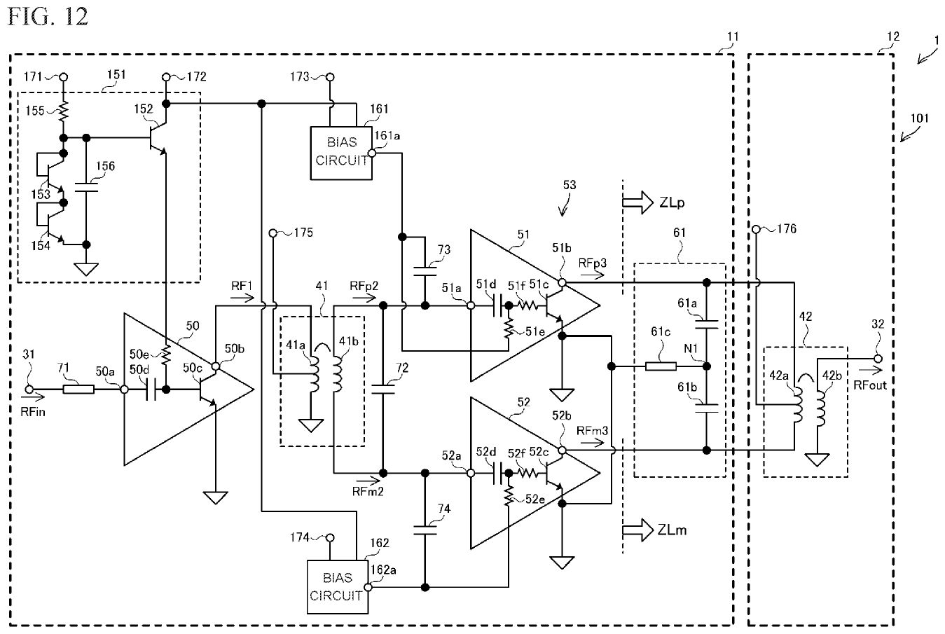

A semiconductor device 1 according to a fourth embodiment will be described. FIG. 12 is a diagram illustrating the semiconductor device 1. As illustrated in FIG. 12, the semiconductor device 1 according to the fourth embodiment is different from the power amplifier circuit 101 according to the first embodiment in that the power amplifier circuit 101 is formed over the semiconductor chip 11 and the printed board 12.

The semiconductor device 1 (power amplifier apparatus) includes a semiconductor chip 11 and a printed board 12. The semiconductor chip 11 is mounted on the printed board 12. A balun 41, a driver-stage amplifier 50, a differential pair 53, a matching circuit 61, a microstrip line 71, capacitors 72, 73, and 74, a driver-stage bias supply circuit 151, and power-stage bias supply circuits 161 and 162 are formed at the semiconductor chip 11. The ground to which the differential pair 53 and the matching circuit 61 are connected is provided at the semiconductor chip 11. The matching circuit 62 or 63 may be formed at the semiconductor chip 11 instead of the matching circuit 61.

A balun 42 is formed at the printed board 12. The ground to which the balun 42 is connected is provided at the printed board 12.

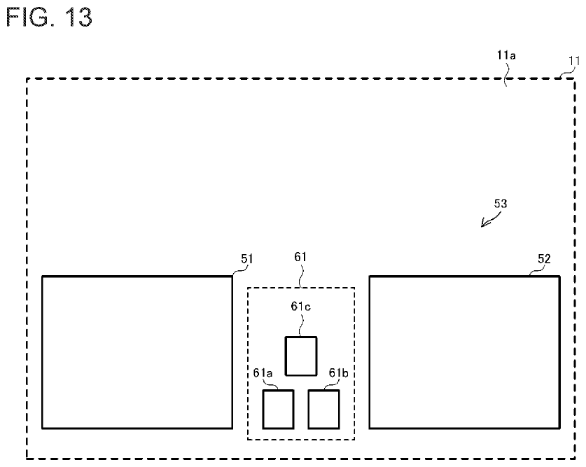

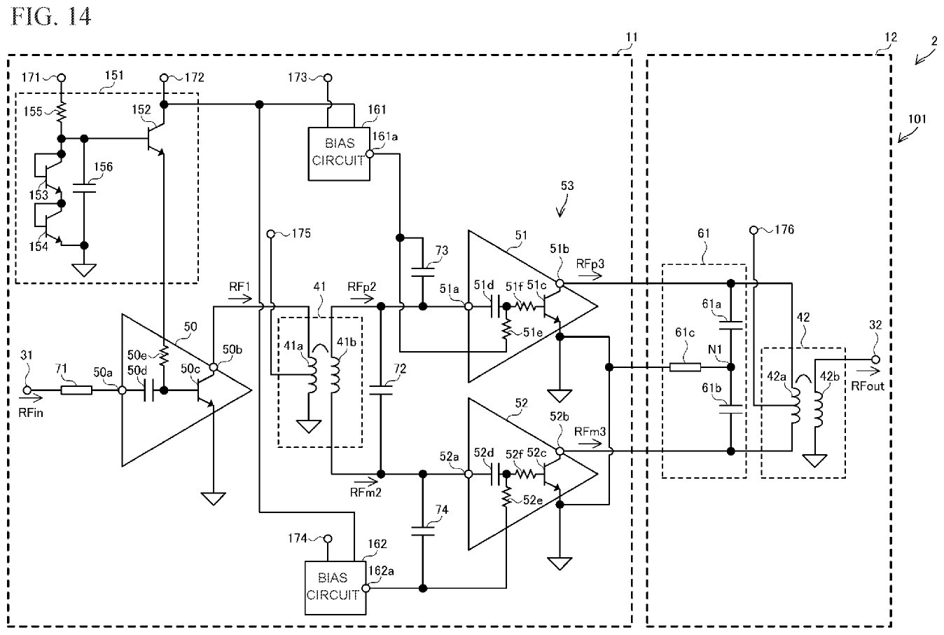

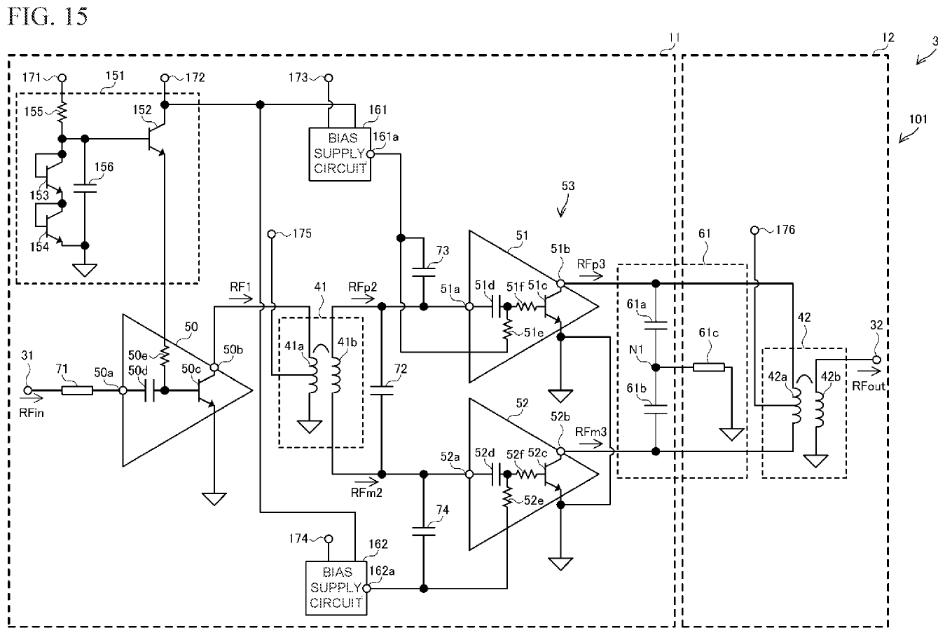

FIG. 13 is a diagram schematically illustrating a layout of the semiconductor chip 11. As illustrated in FIG. 13, the semiconductor chip 11 has a main surface 11a. In the semiconductor chip 11, when the semiconductor chip 11 is viewed in plan view along a direction perpendicular to the main surface 11a, the matching circuit 61 is located between the power-stage amplifier 51 and the power-stage amplifier 52.

### Fifth Embodiment

A semiconductor device 2 according to a fifth embodiment will be described. FIG. 14 is a diagram illustrating the semiconductor device 2. As illustrated in FIG. 14, the semiconductor device 2 according to the fifth embodiment is different from the semiconductor device 1 according to the fourth embodiment in that the matching circuit 61 is formed at the printed board 12.

A balun 41, a driver-stage amplifier 50, a differential pair 53, a microstrip line 71, capacitors 72, 73, and 74, a driver-stage bias supply circuit 151, and power-stage bias supply circuits 161 and 162 are formed at a semiconductor chip 11.

A balun 42 and a matching circuit 61 are formed at the printed board 12. The ground to which the differential pair 53 and the matching circuit 61 are connected is provided at the semiconductor chip 11. The ground to which the balun 42 is connected is provided at the printed board 12. The matching circuit 62 or 63 may be formed at the printed board 12 instead of the matching circuit 61.

### Sixth Embodiment

A semiconductor device 3 according to a sixth embodiment will be described. FIG. 15 is a diagram illustrating the semiconductor device 3. As illustrated in FIG. 15, the semiconductor device 3 according to the sixth embodiment is different from the semiconductor device 1 according to the fourth embodiment in that the matching circuit 61 is formed over the semiconductor chip 11 and the printed board 12.

A balun 41, a driver-stage amplifier 50, a differential pair 53, capacitors 61a and 61b in a matching circuit 61, a microstrip line 71, capacitors 72, 73, and 74, a driver-stage bias supply circuit 151, and power-stage bias supply circuits 161 and 162 are formed at the semiconductor chip 11.

A balun 42 and a microstrip line 61c in the matching circuit 61 are formed at the printed board 12. The ground to which the differential pair 53 is connected is provided at the semiconductor chip 11. The ground to which the balun 42 and the matching circuit 61 are connected is provided at the printed board 12. An inductor 61d may be formed at the printed board 12 instead of the microstrip line 61c, and the microstrip line 61c and the capacitor 61e connected in series, or the inductor 61d and the capacitor 61e connected in series may be formed at the printed board 12.

### Seventh Embodiment

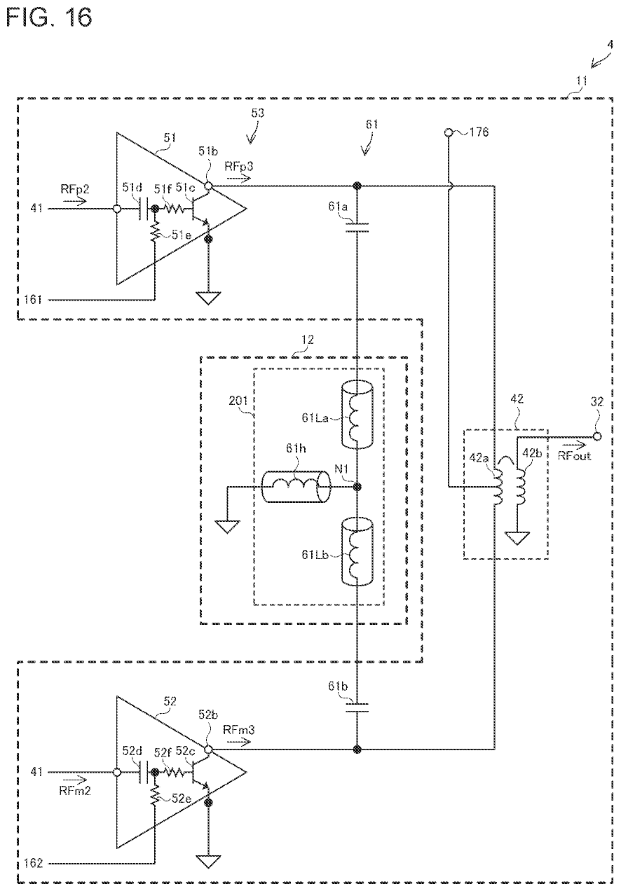

A semiconductor device 4 according to a seventh embodiment will be described. FIG. 16 is a diagram illustrating the semiconductor device 4. A circuit at a stage before the differential pair 53 is not illustrated in FIG. 16. As illustrated in FIG. 16, the semiconductor device 4 according to the seventh embodiment is different from the semiconductor device 1 according to the fourth embodiment in that the balun 42 is provided at the semiconductor chip 11, and the matching circuit 61 is formed over the semiconductor chip 11 and the printed board 12.

Each drawing may illustrate an x-axis, a y-axis, and a z-axis. The x-axis, the y-axis, and the z-axis form a right-handed three-dimensional orthogonal coordinate system. The arrow direction of the x-axis may be referred to as the + side of the x-axis below, and the direction opposite to the arrow may be referred to as the − side of the x-axis below, and the same applies to the other axes. The + side of the z-axis and the − side of the z-axis may be referred to as an “upper side” and a “lower side”, respectively. A z-axis direction may be referred to as a “lamination direction”. In addition, surfaces perpendicular to the x-axis, the y-axis, or the z-axis may be referred to as a yz plane, a zx plane, or an xy plane, respectively. Here, a direction of rotating clockwise when viewed from the upper side to the lower side is defined as a clockwise direction cw. Further, a direction of rotating counterclockwise when viewed from the upper side to the lower side is defined as a counterclockwise direction ccw.

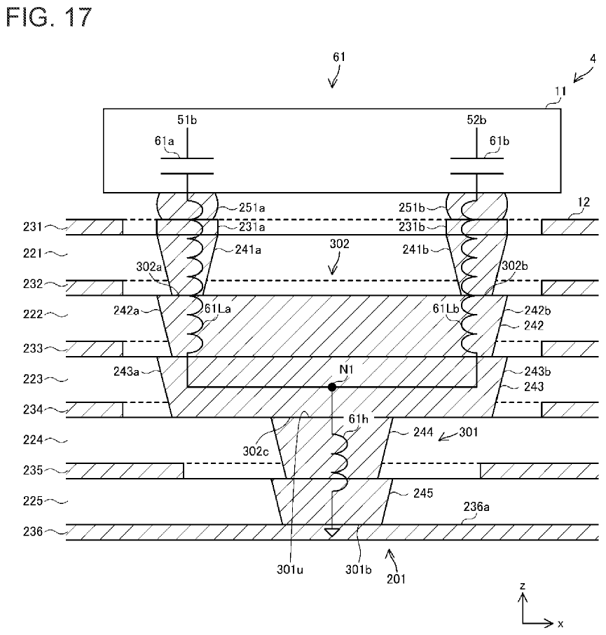

FIG. 17 is a diagram schematically illustrating cross sections of a semiconductor chip 11 in which a matching circuit 61 is formed, and a printed board 12. The cross sections are parallel to the xz plane.

As illustrated in FIGS. 16 and 17, the printed board 12 is a laminated board in which a dielectric layer and a wiring layer are laminated in a lamination direction intersecting with an x-axis direction (second direction). In detail, the printed board 12 includes dielectric layers 221 and 222 (first dielectric layer), 223 (first dielectric layer), 224 (second dielectric layer), and 225 (second dielectric layer), wiring layers 231 and 232 (second wiring layer), 233 and 234 (first wiring layer), and 235 and 236 (third wiring layer).

The dielectric layers 221, 222, 223, 224, and 225 are provided in this order from the upper side to the lower side.

Each of the dielectric layers 121, 122, 123, 124, and 125 includes a surface on an upper side (may be referred to as an upper surface below) that is substantially parallel to the xy plane and a surface on a lower side (may be referred to as a lower surface below) that is substantially parallel to the xy plane. The upper surface of the dielectric layer 122 faces the lower surface of the dielectric layer 121 located on the upper side of the dielectric layer 122. The same applies to other dielectric layers. The upper surface and the lower surface may have unevenness generated at the time of manufacturing, a recess for providing a wiring layer, and the like.

A wiring layer 231 is provided on the upper surface of the dielectric layer 221. The wiring layer 231 includes board-side electrodes 231a and 231b.

A wiring layer 232 is provided between the dielectric layer 221 and the dielectric layer 222. A wiring layer 233 is provided between the dielectric layer 222 and the dielectric layer 223. A wiring layer 234 is provided between the dielectric layer 223 and the dielectric layer 224. A wiring layer 235 is provided between the dielectric layer 224 and the dielectric layer 225.

A wiring layer 236 is provided on the lower surface of the dielectric layer 225. The wiring layer 236 includes a reference electrode 236a to which a reference potential is supplied. The reference electrode 236a is, for example, an electrode that is formed over the entire lower surface of the dielectric layer 225 and is connected to the ground. The reference electrode 236a is not limited to a configuration in which the reference electrode 236a is formed over the entire lower surface of the dielectric layer 225, and may be formed on at least a portion of the lower surface of the dielectric layer 225.

The impedance matching device 201 includes a conductive portion 301 (first conductive portion) and a conductive portion 302 (second conductive portion).

In the present embodiment, the conductive portions 301 and 302 are formed at the printed board 12. A balun 42, a differential pair 53, and capacitors 61a and 61b are formed at the semiconductor chip 11.

The semiconductor chip 11 is provided at the printed board 12. Specifically, the semiconductor chip 11 is flip-chip connected to the printed board 12 in a manner that bumps 251a and 251d are connected to the board-side electrodes 231a and 231b, respectively.

The conductive portion 301 extends in the z-axis direction (first direction) and includes an end portion 301b (first end portion) that is electrically connected to the reference electrode 236a and an end portion 301u (second end portion).

In the present embodiment, the conductive portion 301 includes vias 244 (second via) and 245 (second via) provided in the dielectric layers 224 and 225, respectively. The conductive portion 301 electrically connects the wiring layers 234 and 236.

Specifically, the vias 244 and 245 have a tapered shape in which the lower side is thinner than the upper side. The vias 244 and 245 are joined to each other in the lamination direction.

A surface of the via 245 on the lower side is the end portion 301b that is electrically connected to the reference electrode 236a of the wiring layer 236. The surface of the via 244 on the upper side is the end portion 301u.

The conductive portion 302 extends in the x-axis direction and includes end portions 242a (third end portion) and 243a (third end portion), and end portions 242b (fourth end portion) and 243b (fourth end portion).

In the present embodiment, the conductive portion 302 includes long hole vias 242 (first via) and 243 (first via) provided in the dielectric layers 222 and 223, respectively. The conductive portion 302 electrically connects the wiring layers 234 and 232.

Specifically, the end portions 242a and 243a are the end portions of the long hole vias 242 and 243 on the − side of the x-axis, respectively. The end portions 242b and 243b are the end portions of the long hole vias 242 and 243 on the + side of the x-axis, respectively.

The long hole vias 242 and 243 have a tapered shape in which the lower side is thinner than the upper side. The long hole vias 242 and 243 are joined to each other in the lamination direction.

The size of each of the long hole vias 242 and 243 in the x-axis direction is larger than the size in the y-axis direction. In detail, in a cross section of each of the long hole vias 242 and 243, which is parallel to the xy plane, the diameter in the x-axis direction is longer than the diameter in the y-axis direction.

The area of the cross section of each of the long hole vias 242 and 243, which is parallel to the xy plane, is, for example, larger than the area of the cross section of each of the vias 244 and 245, which is parallel to the xy plane. The area of the cross section of each of the long hole vias 242 and 243, which is parallel to the xy plane, may be equal to or smaller than the area of the cross section of each of the vias 244 and 245, which is parallel to the xy plane.

The conductive portion 302 further includes connection portions 302a (first connection portion), 302b (second connection portion), and 302c (third connection portion).

The connection portion 302a is electrically connected to the output terminal 51b of the power-stage amplifier 51, which is one in the differential pair 53, through the capacitor 61a, and is located closer to the end portions 242a and 243a than the end portions 242b and 243b.

In the present embodiment, the connection portion 302a is located on the − side of the x-axis of the center of the surface on the surface of the long hole via 242 on the upper side. The connection portion 302a is electrically connected to the second end of the capacitor 61a through a via 241a formed in the dielectric layer 221, the board-side electrode 231a, and the bump 251a.

The connection portion 302b is electrically connected to the output terminal 52b of the power-stage amplifier 52, which is the other in the differential pair 53, through the capacitor 61b, and is located closer to the end portions 242b and 243b than to the end portions 242a and 243a.

In the present embodiment, the connection portion 302b is located on the + side of the x-axis of the center of the surface on the surface of the long hole via 242 on the upper side. The connection portion 302b is electrically connected to the second end of the capacitor 61b through a via 241b formed in the dielectric layer 221, the board-side electrode 231b, and a bump 251b.

The connection portion 302c is electrically connected to the end portion 301u of the conductive portion 301. The connection portion 302c is located closer to the end portions 242b and 243b than the connection portion 302a, and is located closer to the end portions 242a and 243a than the connection portion 302b.

In the present embodiment, a distance between the connection portion 302a and the connection portion 302c (may be referred to as a first distance below) is 0.86 times or more and 1.14 times or less of a distance between the connection portion 302b and the connection portion 302c (may be referred to as a second distance below). Preferably, the first distance is 0.93 times or more and 1.07 times or less of the second distance.

Specifically, the first distance and the second distance are substantially the same. The conductive portions 301 and 302 have a shape that is substantially symmetrical on a surface parallel to the yz plane. More specifically, the connection portion 302c is located at substantially the center of the surface of the long hole via 243 on the lower side. The connection portion 302c is electrically connected to the upper surface of the via 244 formed in the dielectric layer 224.

The conductive portion 301 functions as an inductor 61h provided between the node N1 and the ground. The bump 251a, the board-side electrode 231a, the via 241a, a portion of the long hole via 242, and a portion of the long hole via 243 function as a parasitic inductor 61La between the capacitor 61a and the node N1. The bump 251b, the board-side electrode 231b, the via 241b, another portion of the long hole via 242, and another portion of the long hole via 243 function as a parasitic inductor 61Lb between the capacitor 61b and the node N1.

A configuration in which the conductive portion 302 includes two long hole vias 242 and 243 in the impedance matching device 201 has been described, but the present embodiment is not limited thereto. The conductive portion 302 may be configured to include one or three or more long hole vias. For example, by providing a long hole via joined to the long hole vias 243 and 242 in the lamination direction in the dielectric layer 221, it is possible to increase the thickness of the conductive portion 302 in the lamination direction. As a result, it is possible to effectively reduce the inductance of the parasitic inductor 61La and the inductance of the parasitic inductor 61Lb.

In addition, a configuration in which the conductive portion 302 includes the long hole via 242 in the impedance matching device 201 has been described, but the present embodiment is not limited thereto. For example, a via having a substantially circular cross section may be provided in the dielectric layer 222. Similarly, for example, a via having a substantially circular cross section may be provided in the dielectric layer 223.

In addition, a configuration in which the conductive portion 302 includes one long hole via 242 in the impedance matching device 201 has been described, but the present embodiment is not limited thereto. The conductive portion 302 may be configured to include a plurality of vias provided in parallel in at least one of the dielectric layers 222 and 223, for example. As a result, it is possible to increase the area of the cross section of the conductive portion 302, which is parallel to the xy plane can increase, so that it is possible to effectively reduce the inductance of the parasitic inductor 61La and the inductance of the parasitic inductor 61Lb.

A configuration in which the conductive portion 301 includes two vias 244 and 245 in the impedance matching device 201 has been described, but the present embodiment is not limited thereto. The conductive portion 301 may be configured to include one or three or more vias.

### Eighth Embodiment

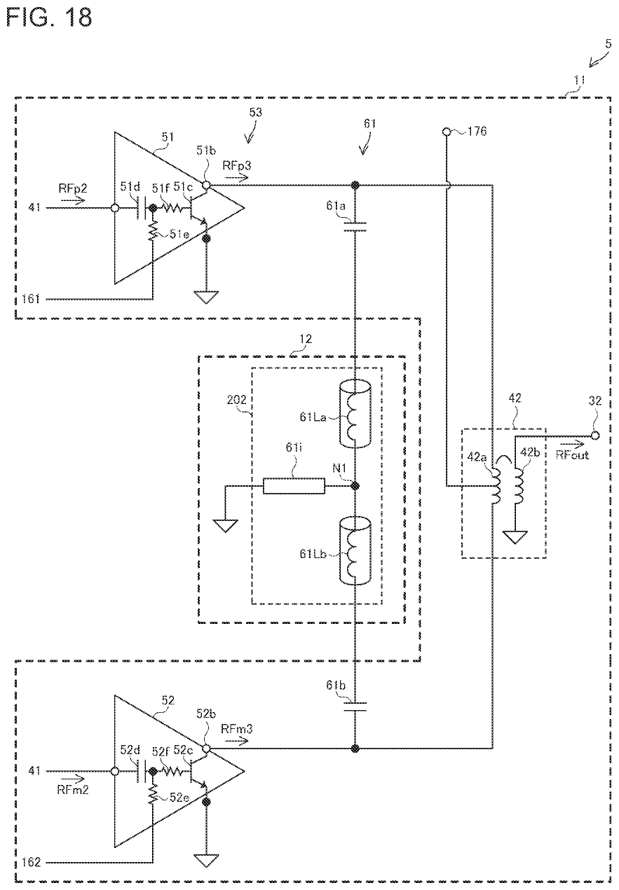

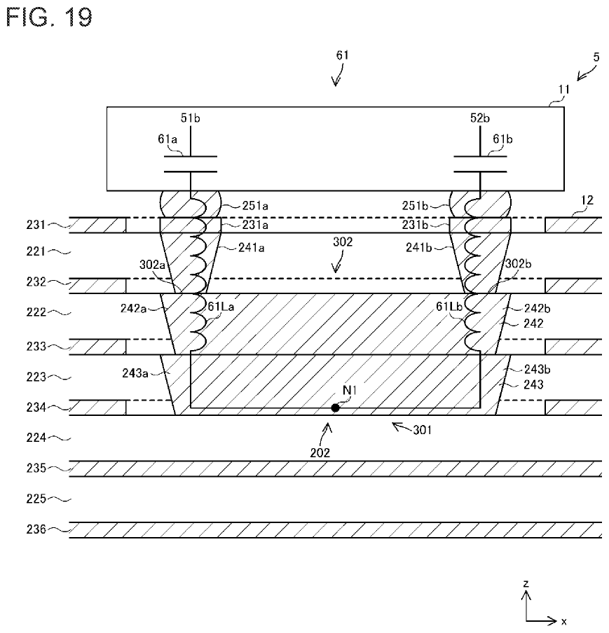

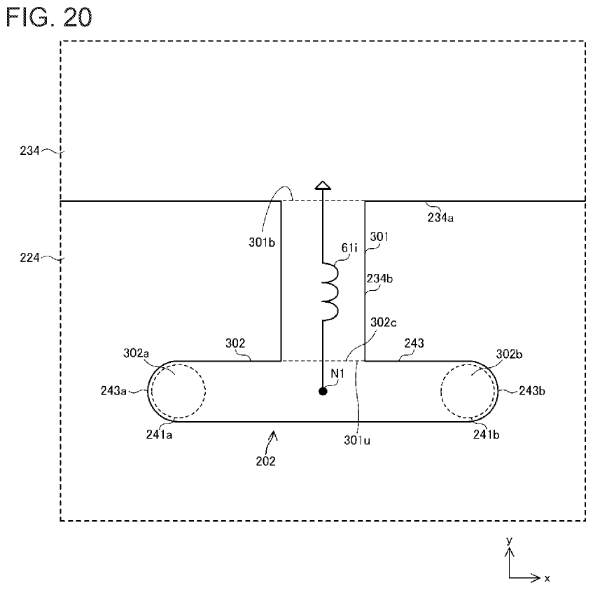

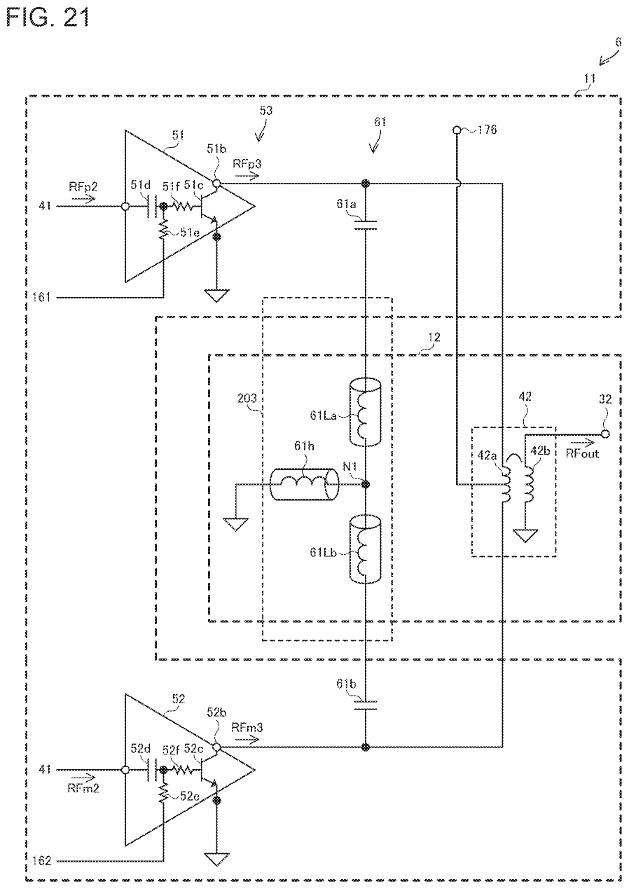

A semiconductor device 5 according to an eighth embodiment will be described. FIG. 18 is a diagram illustrating the semiconductor device 5. FIG. 19 is a diagram schematically illustrating cross sections of a semiconductor chip 11 in which a matching circuit 61 is formed, and a printed board 12. The cross sections are parallel to the xz plane. FIG. 20 is a plan view of a dielectric layer 224 and a wiring layer 234 when viewed from an upper side. A circuit at a stage before a differential pair 53 is not illustrated in FIG. 18.

As illustrated in FIGS. 18 to 20, the semiconductor device 5 according to the eighth embodiment is different from the semiconductor device 4 according to the seventh embodiment in that the conductive portion 301 serves as an electrode of the wiring layer.

The semiconductor device 5 includes an impedance matching device 202 instead of the impedance matching device 201, as compared with the semiconductor device 4 illustrated in FIGS. 16 and 17.

In the impedance matching device 202, a conductive portion 301 includes an electrode 234b instead of the vias 244 and 245, as compared with the conductive portion 301 illustrated in FIGS. 16 and 17.

The conductive portion 301 includes the electrode 234b that is formed in the wiring layer 234 and electrically connects the long hole via 243 and a reference electrode 234a. The conductive portion 301 extends in the y-axis direction intersecting with the x-axis direction (first direction) and the lamination direction.

In detail, the wiring layer 234 includes the reference electrode 234a to which a reference potential is supplied, and an electrode 234b. When the impedance matching device 202 is viewed along the lamination direction in a plan view, the reference electrode 234a and the electrode 234b are located on the + side of the y-axis of the conductive portion 302.

In the present embodiment, the electrode 234b has a substantially rectangular shape when the impedance matching device 202 is viewed along the lamination direction in the plan view. The end portion 301b of the electrode 234b on the + side of the y-axis is connected to the reference electrode 234a. The end portion 301u of the electrode 234b on the − side of the y-axis is electrically connected to the connection portion 302c of the conductive portion 302. The conductive portion 301 functions as an inductor 61i provided between the node N1 and the ground.

In the present embodiment, the first distance and the second distance are substantially the same. The conductive portions 301 and 302 have a shape that is substantially symmetrical on a surface parallel to the yz plane.

### Ninth Embodiment

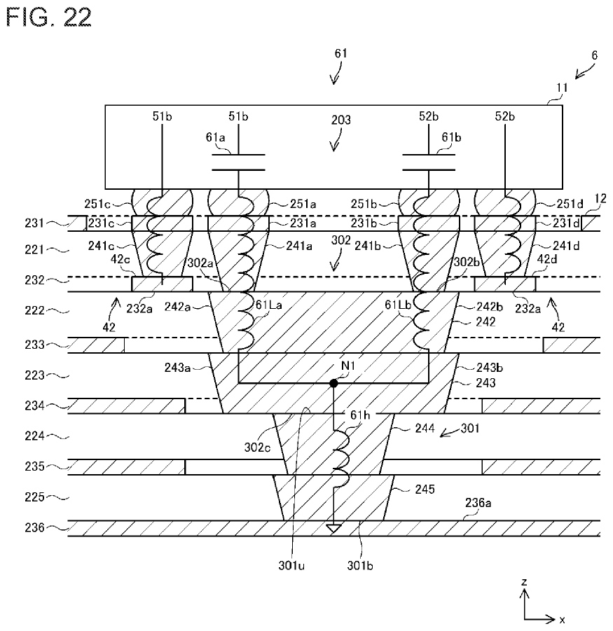

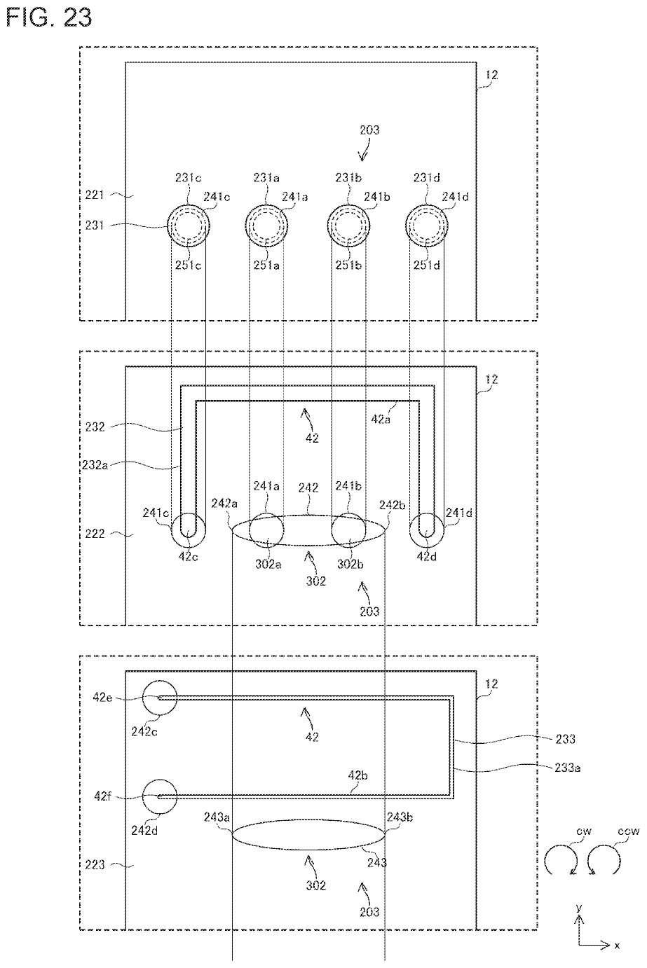

A semiconductor device 6 according to a ninth embodiment will be described. FIG. 21 is a diagram illustrating the semiconductor device 6. FIG. 22 is a diagram schematically illustrating cross sections of a semiconductor chip 11 in which a matching circuit 61 is formed, and a printed board 12. The cross sections are parallel to the xz plane. FIG. 23 is a diagram schematically illustrating each cross section of the printed board 12 in which a balun 42 is formed. The cross section is parallel to the xy plane. A circuit at a stage before a differential pair 53 is not illustrated in FIG. 21.

As illustrated in FIGS. 21 to 23, the semiconductor device 6 according to the ninth embodiment is different from the semiconductor device 4 according to the seventh embodiment in that the balun 42 is provided at the printed board 12.

An impedance matching device 203 further includes bumps 251a (second bump), 251c (first bump), 251d (third bump), and 251b (fourth bump), as compared with the impedance matching device 201 illustrated in FIGS. 16 and 17. A wiring layer 231 further includes board-side electrodes 231c and 231d.

The layout of the bumps, the vias, and the electrodes will be described below. FIG. 23 illustrates a diagram of a dielectric layer 221 and the wiring layer 231 when viewed from the upper side, a diagram of a dielectric layer 222 and a wiring layer 232 when viewed from the upper side, and a diagram of a dielectric layer 223 and a wiring layer 233 when viewed from the upper side.

The output terminal 51b of the power-stage amplifier 51 is electrically connected to the input terminal 42c (first input terminal) of the balun 42 formed at the wiring layer 232 through the bump 251c, the board-side electrode 231c, and the via 241c formed in the dielectric layer 221. In addition, the output terminal 51b is electrically connected to the connection portion 302a of the conductive portion 302 through the capacitor 61a, the bump 251a, the board-side electrode 231a, and the via 241a.

The output terminal 52b of the power-stage amplifier 52 is electrically connected to the input terminal 42d (second input terminal) of the balun 42 formed at the wiring layer 232 through the bump 251d, the board-side electrode 231d, and the via 241d formed in the dielectric layer 221. In addition, the output terminal 52b is electrically connected to the connection portion 302b of the conductive portion 302 through the capacitor 61b, the bump 251b, the board-side electrode 231b, and the via 241b.

The bumps 251a and 251b are located between the bump 251c and the bump 251d. In detail, the bumps 251c, 251a, 251b, and 251d are provided in this order from the − side of the x-axis to the + side of the x-axis, and are arranged in a row to be substantially parallel to the x-axis.

The vias 241c, 241a, 241b, and 241d overlap the bumps 251c, 251a, 251b, and 251d, respectively, when the printed board 12 is viewed along the lamination direction in the plan view.

Each of the vias 241c, 241a, 241b, and 241d electrically connects the wiring layer 231 and the wiring layer 232.

The wiring layer 232 includes an electrode 232a. The electrode 232a is formed by patterning the wiring layer 232. The electrode 232a functions as an inductor 42a in the balun 42.

The electrode 232a is routed from the via 241c and electrically connects the via 241c and the via 241d. Here, the phrase “being routed” means being extended to have a predetermined length.

The electrode 232a is wound in a plane in which the wiring layer 232 extends. In detail, the electrode 232a has an input terminal 42c connected to a lower end portion of the via 241c and an input terminal 42d connected to a lower end portion of the via 241d. The electrode 232a is wound from the input terminal 42c to the input terminal 42d in the clockwise direction cw in the xy plane by ¼ turn or more and less than ¾ turn.

The wiring layer 233 includes an electrode 233a. The electrode 233a is formed by patterning the wiring layer 233. The electrode 233a functions as an inductor 42b in the balun 42.

The electrode 233a is routed from the via 242c, and electrically connects the via 242c with the via 242d located on the − side of the y-axis of the via 242c.

The electrode 233a is wound in a plane in which the wiring layer 233 extends. In detail, the electrode 233a has an output terminal 42e connected to the via 242c and a ground terminal 42f connected to the via 242d. The electrode 233a is wound from the via 242c to the via 242d in the clockwise direction cw in the xy plane by ¼ turn or more and less than ¾ turn.

When the printed board 12 is viewed along the lamination direction in the plan view, there is a portion at which the electrode 232a and the electrode 233a overlap each other. As a result, the electrodes 232a and 233a are efficiently electromagnetically coupled.

### Modification Example

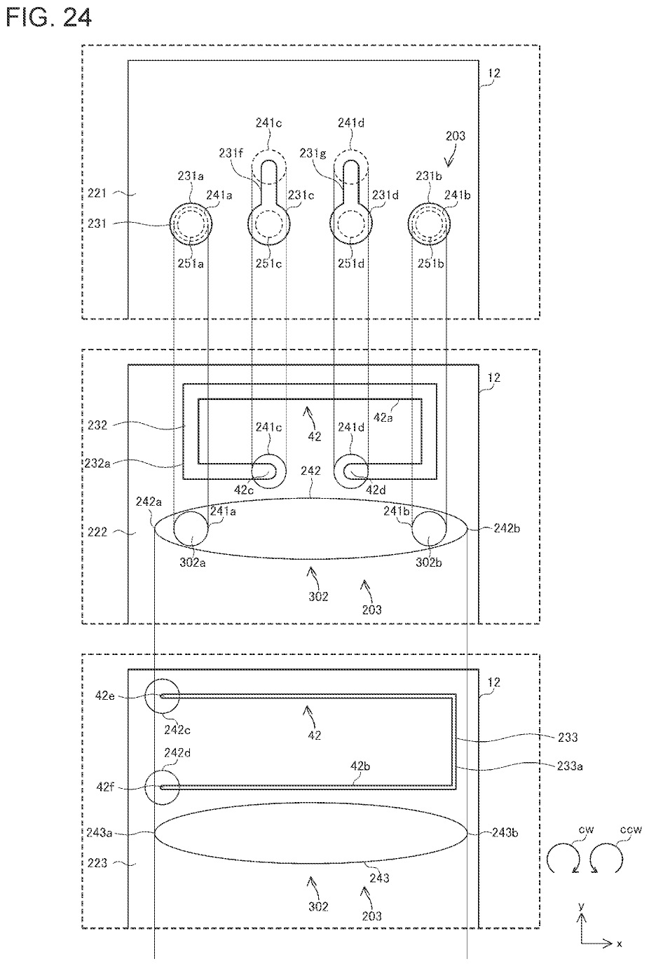

A modification example of the semiconductor device 6 according to the ninth embodiment will be described. FIG. 24 is a diagram schematically illustrating each cross section of the printed board 12 in which the balun 42 is formed. The cross section is parallel to the xy plane.

As illustrated in FIG. 24, the modification example of the semiconductor device 6 according to the ninth embodiment is different from the semiconductor device 6 according to the ninth embodiment in that bumps 251a to 251d are provided in order of the bumps 251a, 251c, 251d, and 251b from the − side of the x-axis to the + side of the x-axis.

FIG. 24 illustrates a diagram of the dielectric layer 221 and the wiring layer 231 when viewed from the upper side, a diagram of the dielectric layer 222 and the wiring layer 232 when viewed from the upper side, and a diagram of the dielectric layer 223 and the wiring layer 233 when viewed from the upper side.

In the modification example of the semiconductor device 6, when the printed board 12 is viewed along the lamination direction in the plan view, the vias 241a and 241b overlap the bumps 251a and 251b, respectively, but the vias 241c and 241d do not overlap the bumps 251c and 251d, respectively.

In detail, the long hole vias 242 and 243 are provided immediately below the vias 241a and 241b. The electrodes 232a and 233a of the balun 42 are provided on the + side of the y-axis of the long hole vias 242 and 243, respectively, in order to avoid physical interference with the long hole vias 242 and 243.

When the printed board 12 is viewed along the lamination direction in the plan view, the vias 241c and 241d are located on the + side of the y-axis of the bumps 251c and 251d, respectively.

The electrodes 231f and 231g are electrodes provided in the wiring layer 231 and extend substantially parallel to the y-axis. The electrode 231f has a first end that is electrically connected to the upper end portion of the via 241c and a second end that is electrically connected to the output terminal 51b through the board-side electrode 231c and the bump 251c.

The electrode 231g has a first end that is electrically connected to the upper end portion of the via 241d and a second end that is electrically connected to the output terminal 52b through the board-side electrode 231d and the bump 251d.

### Tenth Embodiment

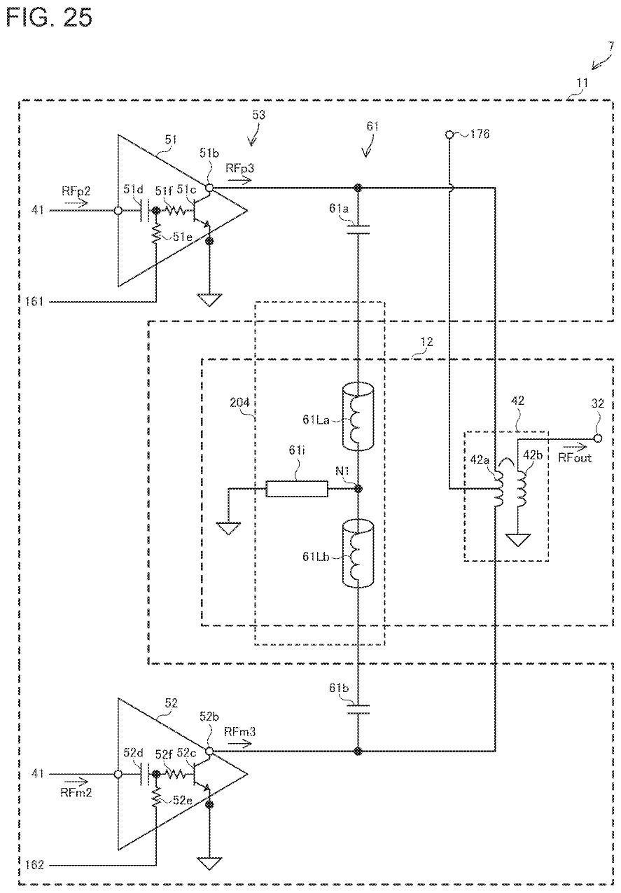

A semiconductor device 7 according to a tenth embodiment will be described. FIG. 25 is a diagram illustrating the semiconductor device 7. A circuit at a stage before a differential pair 53 is not illustrated in FIG. 25.

As illustrated in FIG. 25, the semiconductor device 7 according to the tenth embodiment is different from the semiconductor device 6 according to the ninth embodiment in that an impedance matching device 204 is provided instead of the impedance matching device 203 illustrated in FIGS. 21 to 23. In the impedance matching device 204, the conductive portion 301 serves as the electrode 234b of the wiring layer 234, which functions as the inductor 61i.

### Eleventh Embodiment

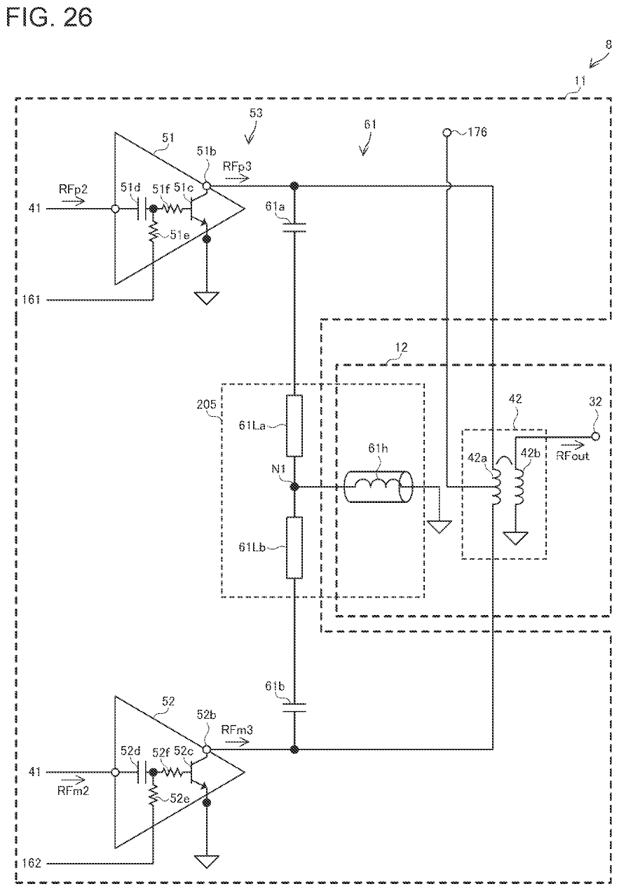

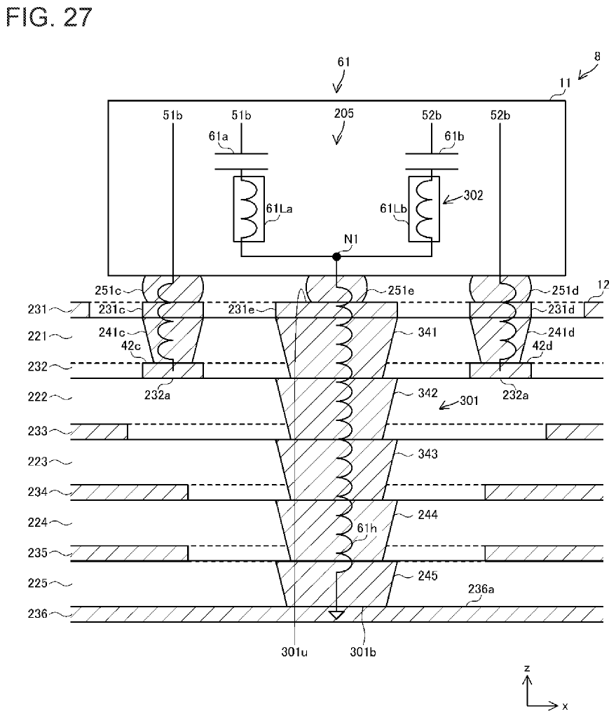

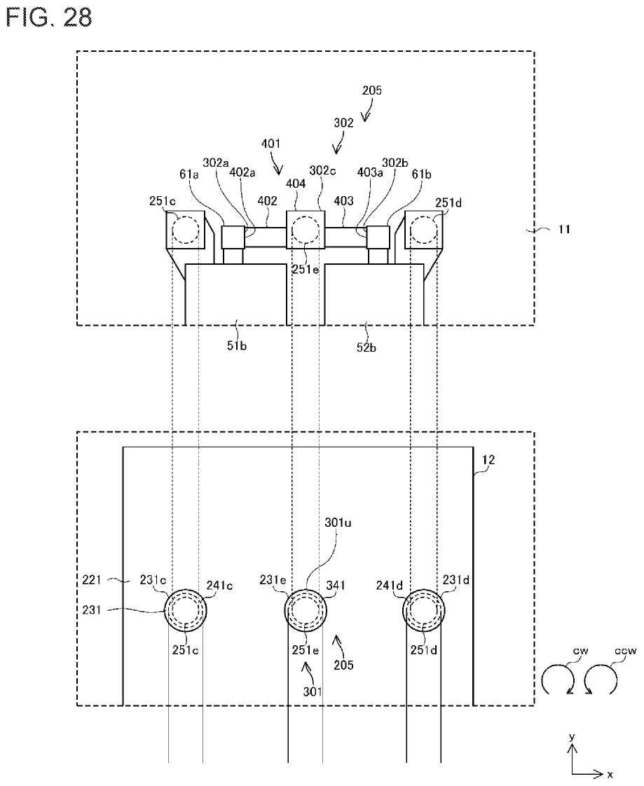

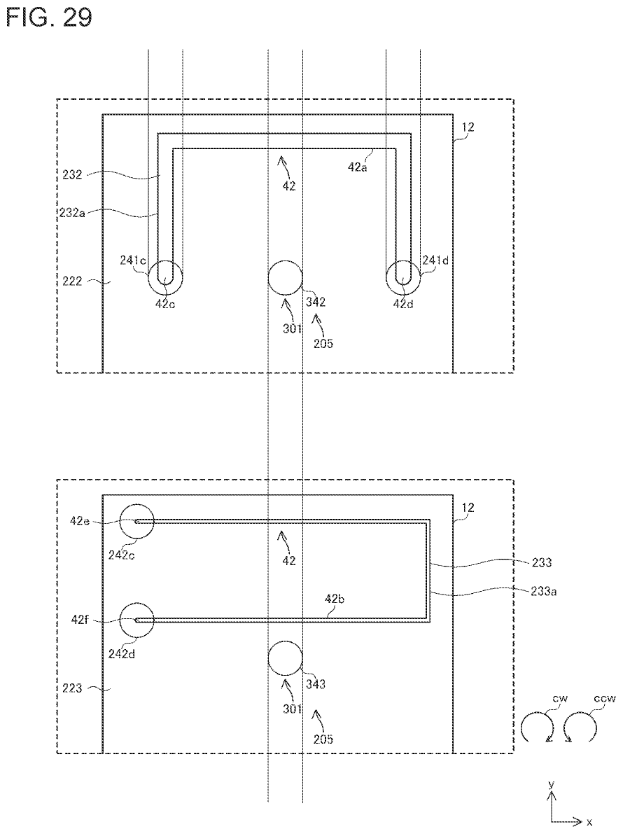

A semiconductor device 8 according to an eleventh embodiment will be described. FIG. 26 is a diagram illustrating the semiconductor device 8. FIG. 27 is a diagram schematically illustrating cross sections of a semiconductor chip 11 in which a matching circuit 61 is formed, and a printed board 12. The cross sections are parallel to the xz plane. FIG. 28 is a diagram schematically illustrating each cross section of the semiconductor chip 11 and the printed board 12, which is parallel to the xy plane. FIG. 29 is a diagram schematically illustrating each cross section of the printed board 12, which is parallel to the xy plane. A circuit at a stage before a differential pair 53 is not illustrated in FIG. 26.

As illustrated in FIGS. 26 to 29, the semiconductor device 8 according to the eleventh embodiment is different from the semiconductor device 6 according to the ninth embodiment in that the conductive portion 302 is formed at the semiconductor chip 11.

An impedance matching device 205 includes conductive portions 301 and 302, and bumps 251c (fifth bump), 251d (sixth bump), and 251e (seventh bump). A wiring layer 231 includes board-side electrodes 231c, 231d, and 231e.

The layout of the bumps, the vias, and the electrodes will be described below. FIG. 28 illustrates a diagram of the semiconductor chip 11 when viewed from the upper side and a diagram of the dielectric layer 221 and the wiring layer 231 when viewed from the upper side. FIG. 29 illustrates a diagram of the dielectric layer 222 and the wiring layer 232 when viewed from the upper side and a diagram of the dielectric layer 223 and the wiring layer 233 when viewed from the upper side.

A differential pair 53, capacitors 61a and 61b, and the conductive portion 302 are formed at the semiconductor chip 11.

The output terminal 51b of the power-stage amplifier 51 is electrically connected to the input terminal 42c of the balun 42 formed at the wiring layer 232 through the bump 251c, the board-side electrode 231c, and the via 241c formed in the dielectric layer 221.

The output terminal 52b of the power-stage amplifier 52 is electrically connected to the input terminal 42d of the balun 42 formed at the wiring layer 232 through the bump 251d, the board-side electrode 231d, and the via 241d formed in the dielectric layer 221.

The conductive portion 302 has end portions 402a (third end portion) and 403a (fourth end portion), and extends in the x-axis direction. In the present embodiment, the conductive portion 302 includes an electrode portion 401. The electrode portion 401 includes electrodes 402, 403, and 404.

The electrode 402 has a substantially rectangular shape when the impedance matching device 205 is viewed along the lamination direction in the plan view. The end portion 402a of the electrode 402 on the − side of the x-axis is a connection portion 302a connected to the second end of the capacitor 61a. The end portion of the electrode 402 on the + side of the x-axis is connected to the electrode 404. The electrode 402 extends substantially parallel to the x-axis from the end portion 402a to the end portion on the + side of the x-axis.

The electrode 403 has a substantially rectangular shape when the impedance matching device 205 is viewed along the lamination direction in the plan view. The end portion 403a of the electrode 403 on the + side of the x-axis is a connection portion 302b connected to the second end of the capacitor 61b. The end portion of the electrode 403 on the − side of the x-axis is connected to the electrode 404. The electrode 403 extends substantially parallel to the x-axis from the end portion 403a to the end portion on the − side of the x-axis.

The electrode 404 is provided between the electrode 402 and the electrode 403. The electrode 404 is a connection portion 302c that is connected to the conductive portion 301 through the bump 251e and the board-side electrode 231e.

The conductive portion 301 is formed at the printed board 12. The conductive portion 301 electrically connects the wiring layers 231 and 236. In the present embodiment, the conductive portion 301 includes a board-side electrode 231e and vias 341, 342, 343, 244, and 245 provided in the dielectric layers 221, 222, 223, 224, and 225, respectively.

The vias 341, 342, 343, 244, and 245 have a tapered shape in which the lower side is thinner than the upper side. The vias 341, 342, 343, 244, and 245 are joined to each other in the lamination direction.

A surface of the via 245 on the lower side is the end portion 301b that is electrically connected to the reference electrode 236a of the wiring layer 236. The surface of the via 341 on the lower side is connected to the board-side electrode 231e of the wiring layer 231. The surface of the board-side electrode 231e on the upper side is an end portion 301u.

The end portion 301u of the conductive portion 301 is electrically connected to the connection portion 302c of the conductive portion 302 through the bump 251e. In the present embodiment, when the impedance matching device 205 is viewed along the lamination direction in the plan view, there is a portion at which the connection portion 302c, the bump 251e, and the conductive portion 301 overlap each other.

The bump 251e is located between the bump 251c and the bump 251d. In detail, the bumps 251c, 251d, and 251e are provided in this order from the − side of the x-axis to the + side of the x-axis, and are arranged in a row to be substantially parallel to the x-axis.

In the present embodiment, the first distance and the second distance are substantially the same. The conductive portions 301 and 302 have a shape that is substantially symmetrical on a surface parallel to the yz plane.

The bump 251e and the conductive portion 301 function as an inductor 61h provided between the node N1 and the ground. The electrode 402 and a portion of the electrode 404 function as a parasitic inductor 61La between the capacitor 61a and the node N1. The electrode 403 and another portion of the electrode 404 function as a parasitic inductor 61Lb between the capacitor 61b and the node N1.

The exemplary embodiments of the present disclosure have been described above. In the power amplifier circuits 101 to 103, the power-stage amplifier 51 amplifies the amplified signal RFp2 which is one of balanced signals, and outputs the amplified signal RFp3 from the output terminal 51b. The power-stage amplifier 52 amplifies the amplified signal RFm2, which is the other of the balanced signals, and outputs the amplified signal RFm3 from the output terminal 52b. The balun 42 generates an output signal RFout from the amplified signals RFp3 and RFm3. The matching circuit 61 is provided between the power-stage amplifiers 51 and 52 and the balun 42. In the matching circuit 61, the capacitor 61a has the first end connected to the output terminal 51b and the second end. The capacitor 61b has the first end that is connected to the output terminal 52b and the second end that is connected to the second end of the capacitor 61a. The wiring has the first end that is connected to the second end of the capacitor 61a and the second end that is connected to the ground.

For even-order harmonic waves, the phase of the amplified signal RFp3 is substantially the same as the phase of the amplified signal RFm3, and thus, no current flows from the output terminal 51b to the output terminal 52b through the capacitors 61a and 61b. Therefore, from the output terminal 51b, it seems that the output terminal 51b is not connected to the output terminal 52b through the capacitors 61a and 61b. Thus, it is difficult to adjust the impedance for the even-order harmonic wave when the matching circuit 61 is viewed from the output terminal 51b, by the capacitors 61a and 61b. On the other hand, with the configuration in which the output terminal 51b is connected to the ground through the capacitor 61a and the wiring, it is possible to adjust the impedance ZLp for an even-order harmonic wave when the matching circuit 61 is viewed from the output terminal 51b, by the capacitance of the capacitor 61a and the inductance of the wiring. Similarly, with the configuration in which the output terminal 52b is connected to the ground through the capacitor 61b and the wiring, it is possible to adjust the impedance ZLm for the odd-order harmonic wave when the matching circuit 61 is viewed from the output terminal 52b, by the capacitance of the capacitor 61b and the inductance of the wiring. As a result, it is possible to control the impedance of the second harmonic wave and the reflection coefficient Γ2 for the second harmonic wave. By controlling the reflection coefficient Γ2, it is possible to bring the input-output phase difference of the signal voltage with respect to the power change of the output signal RFout close to being flat for each of the power-stage amplifiers 51 and 52. As a result, it is possible to improve the linearity of the relationship between the input and the output of each of the power-stage amplifiers 51 and 52. Thus, it is possible to control the impedance of the second harmonic wave and improve the linearity.

In addition, in the power amplifier circuit 102, the inductor 61d, which is a specific example of the wiring, is formed in a spiral shape.

With such a configuration, it is possible to increase the inductance of the inductor 61d. As a result, for example, when the amplified signals RFp3 and RFm3 are low frequency signals, it is possible to set the impedance of the inductor 61d to have a value suitable for controlling the impedance of the second harmonic wave.

In addition, in the power amplifier circuit 101, the microstrip line 61c, which is a specific example of the wiring, is formed in a straight line shape.

With such a configuration, for example, when the amplified signals RFp3 and RFm3 are high frequency signals, it is possible to set the impedance of the microstrip line 61c to have a value suitable for controlling the impedance of the second harmonic wave.

Further, in the power amplifier circuit 103, the capacitor 61e is connected in series to the wiring between the second end of the capacitor 61a and the ground.

With such a configuration, it is possible to increase the degree of freedom for adjusting the impedance between the capacitor 61a and the ground, so that it is possible to precisely adjust the impedance for the even-order harmonic wave.

In addition, in the power amplifier circuits 101 to 103, each of the power-stage amplifiers 51 and 52 operates as an inverse class-F amplifier.

With such a configuration, in a case where each of the power-stage amplifiers 51 and 52 is operated as the inverse class-F amplifier, relatively precise harmonic wave control is required, and thus, the present disclosure can be more usefully applied.

In addition, in the power amplifier circuits 101 to 103, the phase angle of the reflection coefficient Γ2 when the balun 42 is viewed from the output terminal 51b is 20 degrees or more and 120 degrees or less at a frequency twice the frequency of the amplified signal RFp3.

With such a configuration, it is possible to realize the power-added efficiency of 68% or higher, at which favorable characteristics can be generally obtained.

In addition, in the power amplifier circuits 101 to 103, the phase angle of the reflection coefficient Γ2 is 20 degrees or more and 80 degrees or less.

With such a configuration, it is possible to realize the AM-PM characteristics of −1.5 or more and 1.5 or less, at which favorable characteristics can be obtained, and to realize the favorable power-added efficiency.

In addition, in the power amplifier circuits 101 to 103, the phase angle of the reflection coefficient Γ2 is 30 degrees or more and 70 degrees or less.

With such a configuration, it is possible to realize the AM-PM characteristics of −1.0 or more and 1.0 or less, at which favorable characteristics can be obtained, and to realize the more favorable power-added efficiency.

In addition, in the power amplifier circuits 101 to 103, the phase angle of the reflection coefficient Γ2 is 50 degrees or more and 110 degrees or less.

With such a configuration, it is possible to realize the power-added efficiency of 69% or higher, at which further favorable characteristics can be obtained.

Further, in the power amplifier circuits 101 to 103, the phase angle of the reflection coefficient Γ3 when the balun is viewed from the first output terminal is 170 degrees or more and 280 degrees or less at a frequency three times the frequency of the first amplified signal.

With such a configuration, it is possible to easily realize the favorable power-added efficiency.

In addition, in the semiconductor device 1, the power-stage amplifiers 51 and 52 and the matching circuit 61 are formed at the semiconductor chip 11. The balun 42 is formed at the printed board 12, and the semiconductor chip 11 is mounted on the printed board 12.

In a case where the amplified signals RFp3 and RFm3 are high frequency signals, it is often easy to control the impedance of the second harmonic wave when the size of the matching circuit 61 is small. As described above, with a configuration in which the matching circuit 61 is formed at the semiconductor chip 11 suitable for forming a circuit having a small size, it is possible to realize the semiconductor device 1 suitable for a high frequency signal.

In addition, in the semiconductor device 2, the power-stage amplifiers 51 and 52 are formed at the semiconductor chip 11. The matching circuit 61 and the balun 42 are formed at the printed board 12, and the semiconductor chip 11 is mounted on the printed board 12.

In a case where the amplified signals RFp3 and RFm3 are low frequency signals, it is often easy to control the impedance of the second harmonic wave when the size of the matching circuit 61 is large. As described above, with a configuration in which the matching circuit 61 is formed at the printed board 12 suitable for forming a circuit having a large size, it is possible to realize the semiconductor device 2 suitable for a low frequency signal.

In addition, in the semiconductor device 1 or 2, the ground to which the second end of the wiring is connected is provided at the semiconductor chip 11.

With such a configuration, it is possible to easily form the microstrip line 61c or the inductor 61d on the semiconductor chip 11.

In addition, in the semiconductor device 1, the matching circuit 61 is located between the power-stage amplifier 51 and the power-stage amplifier 52 in the semiconductor chip 11.

With such a configuration, it is possible to dispose the matching circuit 61 and the power-stage amplifiers 51 and 52 at the semiconductor chip 11 without generating a wasteful space, so that it is possible to reduce the size of the semiconductor device 1.

Further, in the semiconductor device 3, the power-stage amplifiers 51 and 52 and the capacitors 61a and 61b are formed at the semiconductor chip 11. The microstrip line 61c or the inductor 61d, and the balun 42 are formed at the printed board 12, and the semiconductor chip 11 is mounted on the printed board 12.

With such a configuration, it is possible to easily form the microstrip line 61c or the inductor 61d at the printed board 12, so that it is possible to increase the Q value of the resonance circuit.

In addition, in the semiconductor device 3, the ground to which the second end of the wiring is connected is provided at the printed board 12.

With such a configuration, it is possible to easily form the microstrip line 61c or the inductor 61d at the printed board 12, so that it is possible to increase the Q value of the resonance circuit.

In a case where the band of the second harmonic wave is widened, the capacitances of the capacitors 61a and 61b may increase. Since the capacitor 61a and the parasitic inductor 61La form a resonance circuit, in a case where the capacitance of the capacitor 61a increases, the resonance point deviates unless the parasitic inductor 61La is reduced. Thus, for example, the signal having the frequency of the fundamental wave is affected. The same applies to the capacitor 61b and the parasitic inductor 61Lb.

Regarding this, in the impedance matching devices 201 to 205, the conductive portion 301 has the end portion 301u and the end portion 301b that is electrically connected to the reference electrode 234a or 236a to which the reference potential is supplied, and the conductive portion 301 extends in the first direction (y-axis direction or z-axis direction). The conductive portion 302 has the end portions 242a, 243a, 242b, and 243b or has the end portions 402a and 403a, and extends in the second direction (x-axis direction) intersecting with the first direction. The conductive portion 302 includes the connection portions 302a, 302b, and 302c. The connection portion 302a is electrically connected to the output terminal 51b of the power-stage amplifier 51, which is one in the differential pair 53, through the capacitor 61a. The connection portion 302b is electrically connected to the output terminal 52b of the power-stage amplifier 52, which is the other in the differential pair 53, through the capacitor 61b. The connection portion 302c is electrically connected to the end portion 301u of the conductive portion 301.

As described above, with a configuration in which the conductive portion 302 extends in the second direction (x-axis direction), the conductive portion 302 can be brought close to a straight line shape. Thus, it is possible to reduce the distance between the connection portion 302a and the connection portion 302c. As a result, it is possible to reduce the parasitic inductor 61La. Similarly, it is possible to reduce the distance between the connection portion 302b and the connection portion 302c, so that it is possible to reduce the parasitic inductor 61Lb. As a result, in a case where the capacitances of the capacitors 61a and 61b are large, it is possible to suppress the deviation of the resonance point. Thus, it is possible to suppress the influence on the signal having the frequency of the fundamental wave. For example, in a case where a signal in which the frequency of the fundamental wave is included in a frequency band (for example, WiFi band) exceeding 5 GHz is amplified, when the capacitances of the capacitors 61a and 61b are intended to increase in order to widen the band of the second harmonic wave, the impedance matching devices 201 to 205 having small parasitic inductors 61La and 61Lb can be provided.

In addition, in the impedance matching devices 201 to 205, the connection portion 302a is located closer to the end portions 242a and 243a than to the end portions 242b and 243b, or is located closer to the end portion 402a than to the end portion 403a. The connection portion 302b is located closer to the end portions 242b and 243b than to the end portions 242a and 243a, or is located closer to the end portion 403a than to the end portion 402a. The connection portion 302c is located closer to the end portions 242b and 243b than the connection portion 302a, or is located close to the end portion 403a, and is located closer to the end portions 242a and 243a than the connection portion 302b or is located close to the end portion 402a.

As described above, with a configuration in which the connection portion 302c is located closer to the end portions 242b and 243b than the connection portion 302a or close to the end portion 403a, and is located closer to the end portions 242a and 243a than the connection portion 302b or is located close to the end portion 402a, it is possible to suppress an occurrence of a situation in which the inductance of the parasitic inductor 61La is largely different from the inductance of the parasitic inductor 61Lb. As a result, it is possible to realize a well-balanced matching circuit 61.

In addition, in the impedance matching devices 201 to 204, the conductive portions 301 and 302 are formed at the printed board 12 having the lamination direction (z-axis direction) that is the direction intersecting with the second direction. The differential pair 53 and the capacitors 61a and 61b are formed at the semiconductor chip 11 provided at the printed board 12. The printed board 12 includes the wiring layer 234, the wiring layer 232 located between the wiring layer 234 and the semiconductor chip 11, and the dielectric layers 222 and 223 located between the wiring layer 234 and the wiring layer 232. The conductive portion 302 includes the long hole vias 242 and 243 that electrically connect the wiring layers 234 and 232 and are provided in the dielectric layers 222 and 223, respectively.

As described above, with a configuration in which the conductive portion 302 includes the long hole vias 242 and 243, it is possible to increase the thickness of the conductive portion 302 in the lamination direction, and thus it is possible to effectively reduce the parasitic inductors 61La and Lb. Further, it is possible to easily realize the conductive portion 302 in the printed board 12.

Further, in the impedance matching devices 201 to 204, the size of each of the long hole vias 242 and 243 in the second direction (x-axis direction) is larger than the size in the direction (y-axis direction) intersecting with the second direction and the lamination direction.

With such a configuration, it is possible to suppress the expansion of the long hole vias 242 and 243 in the direction (y-axis direction) intersecting with the second direction and the lamination direction, and thus, it is possible to reduce an occupied space of the long hole vias 242 and 243 in the printed board 12. As a result, it is possible to ease the restriction on the layout of the matching circuit 61 in the printed board 12.

In addition, in the impedance matching devices 201 and 203, the printed board 12 includes the wiring layer 236 that includes the reference electrode 236a, and in which the wiring layer 234 is located between the wiring layer 236 and the wiring layer 232, and the dielectric layers 224 and 225 located between the wiring layer 236 and the wiring layer 234. The conductive portion 301 includes the vias 244 and 245 that electrically connect the wiring layers 234 and 236 and are provided in the dielectric layers 224 and 225, respectively.

With such a configuration, it is possible to dispose the conductive portions 301 and 302 to be arranged in the lamination direction in the printed board 12, and thus, it is possible to suppress the expansion of the conductive portions 301 and 302 in the direction intersecting with the lamination direction. As a result, it is possible to compactly dispose the conductive portions 301 and 302 in the printed board 12.

Further, in the impedance matching devices 202 and 204, the wiring layer 234 includes the reference electrode 234a. The conductive portion 301 is formed in the wiring layer 234, extends in the direction (y-axis direction) intersecting with the first direction (x-axis direction) and the lamination direction (z-axis direction), and includes the electrode 234b that electrically connects the long hole via 243 and the reference electrode 234a.

As described above, with a configuration in which the wiring layer 234 to which the conductive portion 301 is connected includes the reference electrode 234a, and the electrode 234b electrically connects the conductive portion 301 and the reference electrode 234a, it is possible to shorten the wiring layer included in the printed board 12. Therefore, it is possible to easily realize the thickness reduction and cost reduction of the printed board 12.

For example, in the modification example of the semiconductor device 6 illustrated in FIG. 24, the conductive portion 302 is located on the lower side of the bumps 251c and 251d. In order to suppress the physical interference with the conductive portion 302, the vias 241c and 241d are provided on the + side of the y-axis of the respective bumps 251c and 251d instead of being provided immediately below the respective bumps 251c and 251d.

Therefore, the positions at which the electrodes 232a and 233a of the balun 42 are provided is restricted such that the positions need to be on the + side of the y-axis of the long hole vias 242 and 243. Further, since the distance between the via 241a and the via 241b increases, the long hole vias 242 and 243 extend long in the x-axis direction, the long hole vias 242 and 243 occupy a large space in the printed board 12, and the inductances of the parasitic inductors 61La and 61Lb increase.

On the other hand, in the impedance matching devices 203 and 204, the conductive portions 301 and 302 are formed at the printed board 12 having the lamination direction (z-axis direction) that is the direction intersecting with the second direction. The differential pair 53 and the capacitors 61a and 61b are formed at the semiconductor chip 11 provided at the printed board 12. The bumps 251c, 251a, 251d, and 251b are provided between the semiconductor chip 11 and the printed board 12. The output terminal 51b is electrically connected to the input terminal 42c of the balun 42 formed at the printed board 12 through the bump 251c, and is electrically connected to the connection portion 302a of the conductive portion 302 through the capacitor 61a and the bump 251a. The output terminal 52b is electrically connected to the input terminal 42d of the balun 42 through the bump 251d, and is electrically connected to the connection portion 302b of the conductive portion 302 through the capacitor 61b and the bump 251b. The bumps 251a and 251b are located between the bumps 251c and 251d.

With such a configuration, even though the vias 241c and 241d are provided immediately below the respective bumps 251c and 251d, the vias 241c and 241d do not physically interfere with the conductive portion 302, so that it is possible to simplify the layout and design of the balun 42. Further, since it is possible to reduce the distance between the via 241a and the via 241b, it is possible to suppress an occurrence of a situation in which the long hole vias 242 and 243 extend long in the x-axis direction. As a result, it is possible to reduce the volumes of the long hole vias 242 and 243 in the printed board 12. Further, it is possible to reduce the inductances of the parasitic inductors 61Lb and 61Lb.

In addition, in the impedance matching device 205, the conductive portion 301 is formed at the printed board 12. The differential pair 53, the capacitor 61a, the capacitor 61b, and the conductive portion 302 are formed at the semiconductor chip 11 provided at the printed board 12. The bumps 251c, 251d, and 251e are provided between the semiconductor chip 11 and the printed board 12. The output terminal 51b is electrically connected to the input terminal 42c of the balun 42 formed at the printed board 12 through the bump 251c. The output terminal 52b is electrically connected to the input terminal 42d of the balun 42 through the bump 251d. The end portion 301u is electrically connected to the connection portion 302c of the conductive portion 302 through the bump 251e. The bump 251e is located between the bump 251c and the bump 251d.

As described above, with a configuration in which the conductive portion 302 is formed at the semiconductor chip 11, it is possible to provide a large empty space immediately below the bumps 251c and 251d, so that it is possible to effectively simplify the layout and design of the balun 42.

Further, in the impedance matching devices 201 to 205, the first distance between the connection portion 302a and the connection portion 302c is 0.86 times or more and 1.14 times or less of the second distance between the connection portion 302b and the connection portion 302c.

With such a configuration, it is possible to make the inductance of the parasitic inductor 61La and the inductance of the parasitic inductor 61Lb be substantially the same, so that it is possible to effectively realize the matching circuit 61 with favorable balance.

Each of the embodiments described above is provided for easy understanding of the present disclosure, and does not limit and interpret the present disclosure. The present disclosure may be changed/improved without deviating from the gist of the present disclosure, and the present disclosure also includes equivalents thereof. That is, those in which design changes are made as appropriate to each embodiment by the person skilled in the art are included in the scope of the present disclosure as long as the features of the present disclosure are included. For example, each element provided in each embodiment, the disposition thereof, the material, the condition, the shape, the size, and the like are not limited to those illustrated and can be changed as appropriate. In addition, each of the embodiments is an example, and partial replacement or combination of configurations illustrated in different embodiments is possible, and these are also included in the scope of the present disclosure as long as the features of the present disclosure are included.
1, 2, 3, 4, 5, 6, 7, 8 SEMICONDUCTOR DEVICE
11 SEMICONDUCTOR CHIP
12 PRINTED BOARD
31 INPUT TERMINAL
32 OUTPUT TERMINAL
41, 42 BALUN
50 DRIVER-STAGE AMPLIFIER
50a INPUT TERMINAL
50b OUTPUT TERMINAL
50c AMPLIFICATION TRANSISTOR
50d CAPACITOR
50e RESISTOR ELEMENT
51 POWER-STAGE AMPLIFIER
51a INPUT TERMINAL
51b OUTPUT TERMINAL
51c AMPLIFICATION TRANSISTOR
51d CAPACITOR
51e, 51f RESISTOR ELEMENT
52 POWER-STAGE AMPLIFIER
52a INPUT TERMINAL
52b OUTPUT TERMINAL
52c AMPLIFICATION TRANSISTOR
52d CAPACITOR
52e, 52f RESISTOR ELEMENT
53 DIFFERENTIAL PAIR
61, 62, 63 MATCHING CIRCUIT
61a, 61b, 61e CAPACITOR
61c, 61f, 61g MICROSTRIP LINE
61d, 61h, 61i INDUCTOR
61La, 61Lb PARASITIC INDUCTOR
71 MICROSTRIP LINE
72, 73, 74 CAPACITOR
101, 102, 103 POWER AMPLIFIER CIRCUIT
151 DRIVER-STAGE BIAS SUPPLY CIRCUIT
161, 162 POWER-STAGE BIAS SUPPLY CIRCUIT
201, 202, 203, 204, 205 IMPEDANCE MATCHING DEVICE
221, 222, 223, 224, 225 DIELECTRIC LAYER
231, 232, 233, 234, 235, 236 WIRING LAYER
231a, 231b, 231c, 231d, 231e BOARD-SIDE ELECTRODE
231f, 231g, 232a, 233a, 234b ELECTRODE
234a, 236a REFERENCE ELECTRODE
241a, 241b, 241c, 241d, 242c, 242d, 244, 245 VIA
242, 243 LONG HOLE VIA
242a, 242b, 243a, 243b END PORTION
251a, 251b, 251c, 251d, 251e BUMP
301, 302 CONDUCTIVE PORTION
301b, 301u END PORTION
302a, 302b, 302c CONNECTION PORTION
341, 342, 343 VIA
401 ELECTRODE PORTION
402, 403, 404 ELECTRODE
402a, 403a END PORTION

1. A power amplifier circuit comprising:
a first amplifier configured to amplify a first signal and to output a first amplified signal from a first output terminal, the first signal being one of a pair of balanced signals;
a second amplifier configured to amplify a second signal and to output a second amplified signal from a second output terminal, the second signal being another of the pair of balanced signals;
a balun configured to generate a third signal from the first amplified signal and the second amplified signal; and
a matching circuit that is between the first amplifier and the second amplifier, and the balun,
wherein the matching circuit comprises:
a first capacitor having a first end connected to the first output terminal,
a second capacitor having a first end connected to the second output terminal and a second end connected to a second end of the first capacitor, and
a wiring having a first end connected to the second end of the first capacitor and a second end connected to ground.

2. The power amplifier circuit according to claim 1, wherein the wiring has a spiral shape.

3. The power amplifier circuit according to claim 1, wherein the wiring has a straight line shape.

4. The power amplifier circuit according to claim 1, wherein the matching circuit further comprises a third capacitor connected in series to the wiring, between the second end of the first capacitor and ground.

5. The power amplifier circuit according to claim 1, wherein each of the first amplifier and the second amplifier is an inverse class-F amplifier.

6. The power amplifier circuit according to claim 5, wherein a phase angle of a reflection coefficient when the balun is viewed from the first output terminal is 20 degrees or more and 120 degrees or less at a frequency twice a frequency of the first amplified signal.

7. The power amplifier circuit according to claim 6, wherein the phase angle is 20 degrees or more and 80 degrees or less.

8. The power amplifier circuit according to claim 7, wherein the phase angle is 30 degrees or more and 70 degrees or less.

9. The power amplifier circuit according to claim 6, wherein the phase angle is 50 degrees or more and 110 degrees or less.

10. The power amplifier circuit according to claim 1, wherein a phase angle of a reflection coefficient when the balun is viewed from the first output terminal is 170 degrees or more and 280 degrees or less at a frequency three times a frequency of the first amplified signal.

11. A power amplifier apparatus comprising:
the power amplifier circuit according to claim 1;
a semiconductor chip comprising the first amplifier, the second amplifier, and the matching circuit; and
a board on which the balun is formed, and on which the semiconductor chip is mounted.

12. A power amplifier apparatus comprising:
the power amplifier circuit according to claim 1;
a semiconductor chip comprising the first amplifier and the second amplifier; and
a board on which the matching circuit and the balun are formed, and on which the semiconductor chip is mounted.

13. The power amplifier apparatus according to claim 11, wherein the ground is at the semiconductor chip.

14. The power amplifier apparatus according to claim 12, wherein the ground is at the semiconductor chip.

15. The power amplifier apparatus according to claim 11, wherein in the semiconductor chip, the matching circuit is between the first amplifier and the second amplifier.

16. A power amplifier apparatus comprising:
the power amplifier circuit according to claim 1;
a semiconductor chip comprising the first amplifier, the second amplifier, the first capacitor, and the second capacitor; and
a board on which the wiring and the balun are formed, and on which the semiconductor chip is mounted.

17. The power amplifier apparatus according to claim 16, wherein the ground is at the board.
